(19) United States
(12) Patent Application Publication
(10) Pub. No.: US 2025/0294721 A1
(43) Pub. Date: Sep. 18, 2025

(54) SEMICONDUCTOR DEVICE

(71) Applicant: Samsung Electronics Co., Ltd., Suwon-si (KR)

(72) Inventors: Soyeon KIM, Suwon-si (KR); Suklae KIM, Suwon-si (KR)

(73) Assignee: Samsung Electronics Co., Ltd., Suwon-si (KR)

(21) Appl. No.: 18/944,282

(22) Filed: Nov. 12, 2024

(30) Foreign Application Priority Data
Mar. 15, 2024 (KR) 10-2024-0036390

(51) Int. Cl. H10B 12/00

(52) U.S. Cl. CPC H10B 12/315; H10B 12/09; H10B 12/50

(57) ABSTRACT

A semiconductor device includes an integrated circuit structure including conductive regions; a capacitor including lower electrode structures connected to the conductive regions and spaced apart on the integrated circuit structure, a dielectric layer covering the lower electrode structures, and an upper electrode structure on the dielectric layer; and supporter structures interconnecting the lower electrode structures, the supporter structures include an upper supporter structure interconnecting upper regions of the lower electrode structures and spaced apart, and a lower supporter structure interconnecting the lower electrode structures and spaced apart, side surfaces of the upper supporter patterns and an side surface of the upper region of the lower electrode structures define an upper open pattern, side surfaces of the lower supporter patterns and a side surface of the lower electrode structure define a lower open pattern, and centers of the upper supporter patterns and centers of the lower supporter patterns are aligned.

### CROSS-REFERENCE TO RELATED APPLICATION(S)

This application claims benefit of and priority to Korean Patent Application No. 10-2024-0036390 filed on Mar. 15, 2024 in the Korean Intellectual Property Office, the disclosure of which is incorporated herein by reference in its entirety.

### BACKGROUND

Example embodiments of the present disclosure relate to a semiconductor device.

As demand for high performance, high speed, and/or multifunctionality for a semiconductor device has increased, integration density of a semiconductor device has increased. In manufacturing a semiconductor device having a fine pattern in response to the trend toward integration density of a semiconductor device, it may be necessary to implement patterns having a fine width or a fine spacing distance therebetween.

### SUMMARY

Some example embodiments of the present disclosure provide semiconductor devices including a support structure having various designs depending on the arrangement of a data storage structure.

According to some example embodiments, a semiconductor device includes an integrated circuit structure including conductive regions; a capacitor including lower electrode structures electrically connected to the conductive regions of the integrated circuit structure, a dielectric layer covering the lower electrode structures, and an upper electrode structure on the dielectric layer, the lower electrode structures being spaced apart from each other on the integrated circuit structure; and supporter structures interconnecting the lower electrode structures, wherein the supporter structures include, an upper supporter structure interconnecting upper regions of the lower electrode structures to each other, the upper supporter structure including upper supporter patterns spaced apart from each other, and a lower supporter structure including lower supporter patterns interconnecting the lower electrode structures to each other, the lower supporter patterns spaced apart from each other below the upper supporter patterns, wherein external side surfaces of the upper supporter patterns of the upper supporter structure and external side surfaces of the upper regions of the lower electrode structures connected to each other by the upper supporter patterns define an upper open pattern extending in a horizontal direction, wherein external side surfaces of the lower supporter patterns of the lower supporter structure and external side surfaces of the lower electrode structure connected to each other by the lower supporter patterns define a lower open pattern extending in the horizontal direction, and wherein first centers of the upper supporter patterns of the upper supporter structure and second centers of the lower supporter patterns of the lower supporter structure corresponding to the first centers, respectively, are aligned.

According to some example embodiments, a semiconductor device includes an integrated circuit structure including conductive regions; a capacitor including lower electrode structures electrically connected to the conductive regions of the integrated circuit structure, a dielectric layer covering the lower electrode structures, and an upper electrode structure on the dielectric layer; an upper supporter structure including upper supporter patterns spaced apart from each other, each of the upper supporter patterns surrounds at least one first lower electrode structure of the lower electrode structures and each of the upper supporter patterns is in contact with at least a portion of a side surface of each of a plurality of second lower electrode structures adjacent to the at least on first lower electrode structure; and a lower supporter structure below the upper supporter structure and including lower supporter patterns having centers aligned with centers of the upper supporter patterns, respectively, wherein at least a portion of the upper electrode structure of the capacitor surrounds a side surface of each of the upper supporter patterns and extends in a horizontal direction between the upper supporter patterns, and wherein at least a portion of the upper electrode structure of the capacitor surrounds a side surface of each of the lower supporter patterns and extends in the horizontal direction between the lower supporter patterns.

According to some example embodiments, a semiconductor device includes an integrated circuit structure including conductive regions; a capacitor including lower electrode structures electrically connected to the conductive regions of the integrated circuit structure, a dielectric layer covering the lower electrode structures, and an upper electrode structure on the dielectric layer; and a supporter structure including a supporter pattern group being sequentially located at different levels on the integrated circuit structure, the supporter pattern group surrounds at least one first lower electrode structure of the lower electrode structures on different levels and contacts at least a portion of a side surface of each of a plurality of second lower electrode structures adjacent to the at least one first lower electrode structure, wherein the supporter pattern group of the support structure includes, upper supporter patterns in an upper region of the lower electrode structures and spaced apart from each other in a horizontal direction; intermediate supporter patterns below the upper supporter patterns, and having centers aligned with centers of the upper supporter patterns; and lower supporter patterns between the intermediate supporter patterns and the integrated circuit structure and having centers aligned with centers of the intermediate supporter patterns, respectively, wherein a minimum distance between external side surfaces of the upper supporter patterns adjacent to each other among the upper supporter patterns is greater than a minimum distance between external side surfaces of the intermediate supporter patterns adjacent to each other among the intermediate supporter patterns, and wherein a minimum distance between external side surfaces of the intermediate supporter patterns adjacent to each other among the intermediate supporter patterns is greater than a minimum distance between external side surfaces of the lower supporter patterns adjacent to each other among the lower supporter patterns.

### BRIEF DESCRIPTION OF DRAWINGS

The above described aspects and other aspects, features, and advantages of some example embodiments will be more clearly understood from the following detailed description, taken in combination with the accompanying drawings, in which:

FIG. 1 is a plan diagram illustrating a semiconductor device according to some example embodiments of the present disclosure;

FIG. 2A is an enlarged diagram illustrating a portion of the semiconductor device illustrated in FIG. 1;

FIG. 2B is a cross-sectional diagram illustrating a semiconductor device according to some example embodiments of the present disclosure;

FIG. 2C is a plan diagram illustrating a semiconductor device according to some example embodiments of the present disclosure;

FIG. 3 is a plan diagram illustrating a semiconductor device according to some example embodiments of the present disclosure;

FIGS. 4 and 5 are enlarged diagrams illustrating a portion of a semiconductor device according to some example embodiments of the present disclosure;

FIG. 6A is an enlarged diagram illustrating a portion of the semiconductor device illustrated in FIG. 1;

FIG. 6B is a cross-sectional diagram illustrating a semiconductor according to some example embodiments of the present disclosure;

FIG. 6C is a plan diagram illustrating a semiconductor device according to some example embodiments of the present disclosure;

FIGS. 7 and 8 are enlarged diagram illustrating a portion of a semiconductor device according to some example embodiments of the present disclosure; and

FIGS. 9 to 20 are cross-sectional diagrams illustrating processes of a method of manufacturing semiconductor devices according to some example embodiments of the present disclosure, viewed in a vertical direction.

### DETAILED DESCRIPTION

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular”, “substantially parallel”, or “substantially coplanar” with regard to other elements and/or properties thereof will be understood to be “perpendicular”, “parallel”, or “coplanar”, respectively, with regard to the other elements and/or properties thereof within manufacturing tolerances and/or material tolerances and/or have a deviation in magnitude and/or angle from “perpendicular”, “parallel”, or “coplanar”, respectively, with regard to the other elements and/or properties thereof that is equal to or less than 10% (e.g., a. tolerance of ±10%).

Hereinafter, some example embodiments will be described as follows with reference to the accompanying drawings.

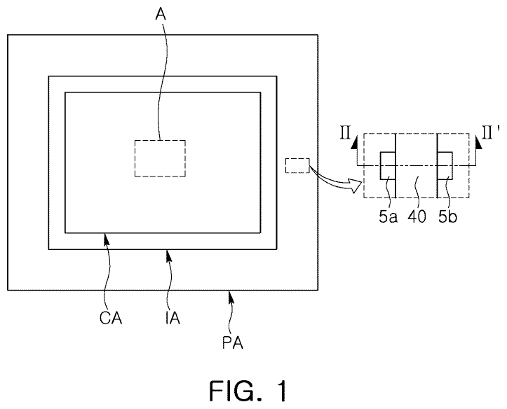

FIG. 1 is a plan diagram illustrating a semiconductor device according to some example embodiments.

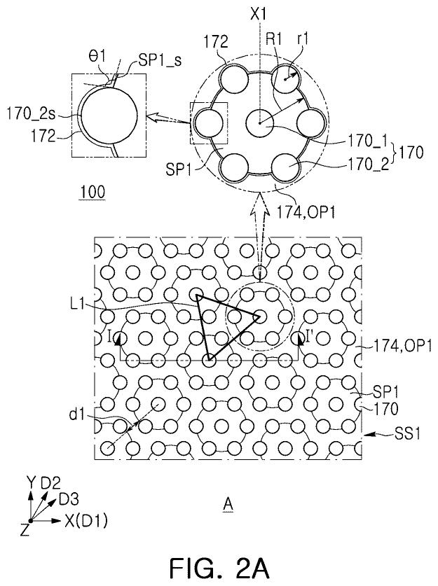

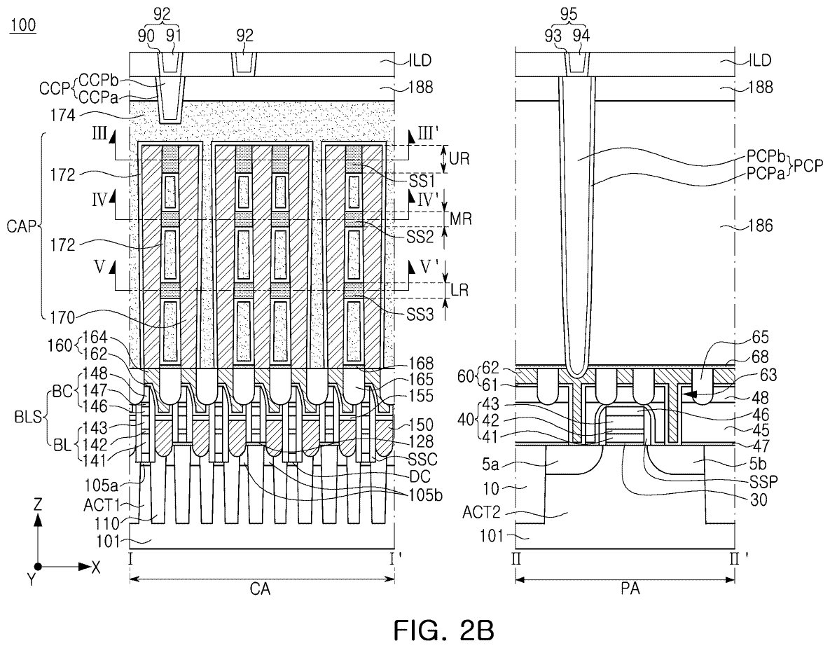

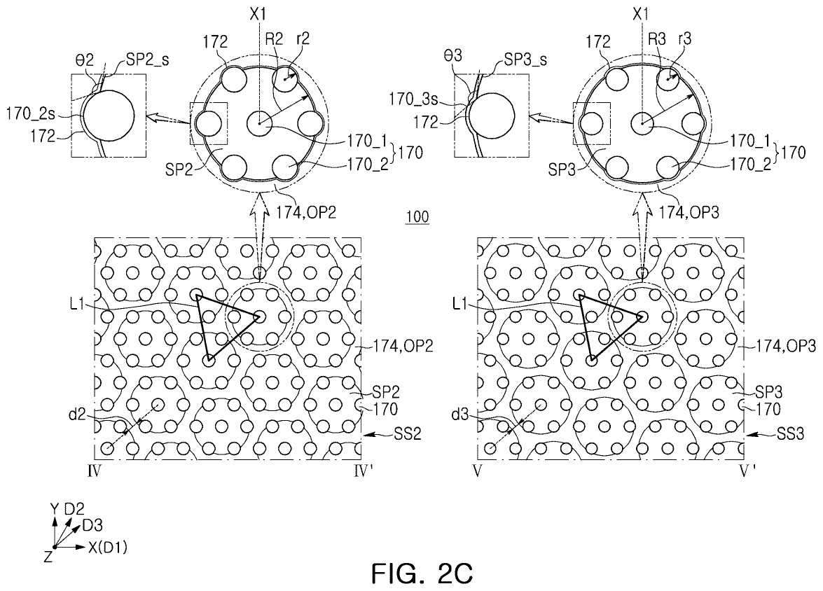

FIG. 2A is an enlarged diagram illustrating region “A” of the semiconductor device illustrated in FIG. 1.

FIG. 2B is a cross-sectional diagram illustrating a semiconductor taken along line I-I′ and II-II′ in FIG. 1 according to some example embodiments. FIG. 2A is a plan diagram illustrating a semiconductor device taken along line III-III′ in FIG. 2B.

FIG. 2C is a plan diagram illustrating a semiconductor device according to some example embodiments.

Referring to FIG. 1, a semiconductor device according to some example embodiments may include a cell region CA, an interface region IA, and a peripheral circuit region PA. The peripheral circuit region PA may surround the cell region CA, and the interface region IA may be disposed between the cell region CA and the peripheral circuit region PA. The cell region CA may refer to a region in which a memory cell of a dynamic random access memory (DRAM) device is disposed, and in the peripheral circuit region PA, a wordline driver, a sense amplifier, a row and column decoders and control circuits may be disposed. The interface region IA may electrically connect the cell region CA to the peripheral circuit region PA.

Referring to FIGS. 2A to 2C, the semiconductor device 100 may include a substrate 101 including first active regions ACT1 disposed in the cell region CA, a device isolation layer 110 defining the first active regions ACT1 in the substrate 101, a bitline structure BLS disposed on the substrate 101 and including the bitline BL, and a data storage structure CAP on the bitline structure BLS. The data storage structure CAP may store data, and may be configured as a capacitor structure of DRAM, for example. In the cell region CA, the semiconductor device 100 may further include a lower conductive pattern 150 on the first active region ACT1, an upper conductive pattern 160 on the lower conductive pattern 150, and an insulating pattern 165 penetrating the upper conductive pattern 160.

Although not illustrated, the semiconductor device 100 may include a wordline disposed in the cell region CA and buried in the substrate 101.

For example, the semiconductor device 100 may include a cell array of dynamic random access memory (DRAM). For example, the bitline BL may be connected to the first impurity region 105a of the first active region ACT1, and the second impurity region 105b of the first active region ACT1 may be electrically connected to the data storage structure CAP on the upper conductive pattern 160 through the lower and upper conductive patterns 150 and 160.

The data storage structure CAP may be configured as a capacitor which may store data in the memory such as DRAM. The data storage structure CAP may be electrically connected to conductive regions 150 and 160, for example, on the lower structure including lower and upper conductive patterns 150 and 160. Here, the lower structure may include the substrate 101, the wordline, and the bitline structure BLS.

The data storage structure CAP may include lower electrode structures 170, a dielectric layer 172 on the lower electrode structures 170, and an upper electrode structure 174 on the dielectric layer 172. The semiconductor device 100 may further include supporter structures SS1, SS2, and SS3 supporting the data storage structure CAP.

The substrate 101 may include a semiconductor material, such as a group IV semiconductor, a group III-V compound semiconductor, or a group II-VI compound semiconductor. For example, a group IV semiconductor may include silicon, germanium, or silicon-germanium. The substrate 101 may further include impurities. The substrate 101 may include a silicon substrate, silicon-on-insulator (SOI) substrate, germanium substrate, germanium-on-insulator (GOI) substrate, silicon-germanium substrate, or a substrate including an epitaxial layer.

The first active regions ACT1 may be defined in the substrate 101 by the device isolation layer 110. The first active region ACT1 may have first and second impurity regions 105a and 105b at a predetermined depth from an upper surface of the substrate 101. The first and second impurity regions 105a and 105b may be spaced apart from each other. The first and second impurity regions 105a and 105b may work as source/drain regions of a transistor including a wordline. The source region and the drain region may be formed by the first and second impurity regions 105a and 105b by doping or ion implantation of substantially the same impurities, and may be referred to interchangeably depending on a circuit configuration of the finally formed transistor. The impurities may include impurities having a conductivity-type opposite to that of the substrate 101. In some example embodiments, the depths of the first and second impurity regions 105a and 105b in the source region and the drain region may be different.

Device isolation layer 110 may be formed by a shallow trench isolation (STI) process. The device isolation layer 110 may surround the first active regions ACT1 and may electrically isolate the first active regions ACT1 from each other. The device isolation layer 110 may be formed of an insulating material, for example, silicon oxide, silicon nitride, or a combination thereof.

Although not illustrated, the wordline may extend in the first direction X across the first active region ACT1. For example, a pair of wordlines adjacent to each other may cross the first active region ACT1. A wordline may be included in a gate of a buried channel array transistor (BCAT), but example embodiments thereof are not limited thereto.

The bitline structure BLS may extend perpendicularly to a wordline in one direction, for example, in the second direction Y. The bitline structure BLS may include a bitline BL and a bitline capping pattern BC on the bitline BL.

The bitline BL may include a first conductive pattern 141, a second conductive pattern 142, and a third conductive pattern 143, stacked in order, for example stacked sequentially in a vertical direction (Z direction as depicted in FIG. 2B). The bitline capping pattern BC may be disposed on the third conductive pattern 143. A buffer insulating layer 128 may be disposed between the first conductive pattern 141 and the substrate 101, and a portion of the first conductive pattern 141 (hereinafter, a bitline contact pattern DC) may be in contact with the first impurity region 105a of the first active region ACT1. The bitline BL may be electrically connected to the first impurity region 105a through the bitline contact pattern DC. A lower surface of the bitline contact pattern DC may be disposed on a level lower than a level of an upper surface of the substrate 101, and may be disposed on a level higher than a level of an upper surface of the wordline. In some example embodiments, a bitline contact pattern DC may be formed in the substrate 101 and may be locally disposed in a bitline contact hole exposing the first impurity region 105a.

The first conductive pattern 141 may include a semiconductor material such as polycrystalline silicon. The first conductive pattern 141 may be in contact, for example direct contact, with the first impurity region 105a. The second conductive pattern 142 may include a metal-semiconductor compound. For example, the metal-semiconductor compound may be configured as a layer siliciding a portion of the first conductive pattern 141. For example, the metal-semiconductor compound may include cobalt silicide (CoSi), titanium silicide (TiSi), nickel silicide (NiSi), tungsten silicide (WSi), or other metal silicide. The third conductive pattern 143 may include a metal material such as titanium (Ti), tantalum (Ta), tungsten (W), and/or aluminum (Al). The number of conductive patterns included in the bitline BL, a type of material thereof, and/or stacking order thereof may be varied some example embodiments.

The bitline capping pattern BC may include a first capping pattern 146, a second capping pattern 147, and a third capping pattern 148 stacked in order on the third conductive pattern 143. Each of the first to third capping patterns 146, 147, and 148 may include an insulating material, for example, a silicon nitride film. The first to third capping patterns 146, 147, and 148 may be formed of different materials, and even when the patterns include the same material, boundaries therebetween may be distinct due to a difference in physical properties. A thickness of the second capping pattern 147 may be smaller than thicknesses of the first capping pattern 146 and the third capping pattern 148. The number of capping patterns included in the bitline capping pattern BC and/or the type of material thereof may be varied in example embodiments.

The spacer structures SSC may be disposed on both sidewalls of the bitline structure BLS, respectively, and may extend in one direction, for example, the Y-direction. The spacer structures SSC may be disposed between the bitline structure BLS and the lower conductive pattern 150. The spacer structures SSC may extend along sidewalls of the bitline BL and sidewalls of the bitline capping pattern BC. A pair of the spacer structures SSC disposed on both sides of the bitline structure BLS may have an asymmetric shape with respect to the bitline structure BLS. Each of the spacer structures SSC may include a plurality of spacer layers and may further include an air spacer in some example embodiments.

The lower conductive pattern 150 may be connected to a region of the first active region ACT1, for example, the second impurity region 105b. The lower conductive pattern 150 may be disposed between the bitlines BL. The lower conductive pattern 150 may penetrate the buffer insulating layer 128 and may be connected to the second impurity region 105b of the first active region ACT1. The lower conductive pattern 150 may be in contact, for example direct contact, with the second impurity region 105b. A lower surface of the lower conductive pattern 150 may be disposed on a level lower than a level of an upper surface of the substrate 101, and may be disposed on a level higher than a level of a lower surface of the bitline contact pattern DC. The lower conductive pattern 150 may be disposed on a higher level than the spacer structure SS, for example on a higher level than a lower surface of the spacer structure SS. The lower conductive pattern 150 may be insulated with the bitline contact pattern DC by the spacer structure SS. The lower conductive pattern 150 may be formed of a conductive material, may include, for example, at least one of polycrystalline silicon (Si), titanium (Ti), titanium nitride (TiN), tantalum (Ta), tantalum nitride (TaN), tungsten (W), tungsten nitride (WN), and/or aluminum (Al). In some example embodiments, the lower conductive pattern 150 may include a plurality of layers.

The metal-semiconductor compound layer 155 may be disposed between the lower conductive pattern 150 and the upper conductive pattern 160. For example, when the lower conductive pattern 150 includes a semiconductor material, the metal-semiconductor compound layer 155 may be configured as a layer siliciding a portion of the lower conductive pattern 150. The metal-semiconductor compound layer 155 may include, for example, cobalt silicide (CoSi), titanium silicide (TiSi), nickel silicide (NiSi), tungsten silicide (Wsi), or other metal silicide. In some example embodiments, the metal-semiconductor compound layer 155 may not be provided.

The upper conductive pattern 160 may be disposed on the lower conductive pattern 150. The upper conductive pattern 160 may extend to a region between the spacer structures SS and may cover an upper surface of the metal-semiconductor compound layer 155. The upper conductive pattern 160 may include a barrier layer 162 and a conductive layer 164. The barrier layer 162 may cover a lower surface and side surfaces of the conductive layer 164. The barrier layer 162 may include at least one of metal nitrides, such as titanium nitride (TiN), tantalum nitride (TaN), and/or tungsten nitride (WN). The conductive layer 164 may include a conductive material, such as, at least one of polycrystalline silicon (Si), titanium (Ti), tantalum (Ta), tungsten (W), ruthenium (Ru), copper (Cu), molybdenum (Mo), platinum (Pt), and nickel (Ni), cobalt (Co), aluminum (Al), titanium nitride (TiN), tantalum nitride (TaN), and/or tungsten nitride (WN).

The insulating patterns 165 may penetrate the upper conductive pattern 160. The upper conductive pattern 160 may be divided into a plurality of portions by the insulating patterns 165. The insulating patterns 165 may include at least one of an insulating material, for example, silicon oxide, silicon nitride, and/or silicon oxynitride.

The etch stop layer 168 may cover the insulating patterns 165 between the first electrode structures 170. The etch stop layer 168 may also extend further into the interface region IA. The etch stop layer 168 may be in contact with a lower region of side surfaces of the first electrode structures 170. The etch stop layer 168 may be disposed below support structures SS1, SS2, and SS3. For example, the etch stop layer may be vertically aligned with the support structures SS1, SS2, and SS3. An upper surface of the etch stop layer 168 may include a portion in contact, for example direct contact, with the dielectric layer 172. For example, the etch stop layer 168 may include at least one of silicon nitride and silicon oxynitride.

The lower electrode structures 170 may be disposed on the upper conductive patterns 160. The lower electrode structures 170 may penetrate the etch stop layer 168 and may be in contact with the upper conductive patterns 160. The lower electrode structures 170 may include at least one of niobium nitride (NbN), niobium oxide (NbOx), polycrystalline silicon (Si), iridium (Ir), titanium (Ti), titanium nitride (TiN), titanium silicide nitride (TiSiN), tantalum (Ta), tantalum nitride (TaN), tungsten (W), tungsten nitride (WN), and/or aluminum (Al) or a combination thereof, metal nitride, and/or metal compound.

Referring to FIG. 2A, in the plan diagram viewed from above, the lower electrode structures 170 may be arranged regularly. In some example embodiments, the lower electrode structures 170 may be spaced apart by a predetermined distance in a first horizontal direction D1 and may be arranged in a second horizontal direction D2 intersecting the first horizontal direction D1. In a different point of view, the first electrode structures 170 may be disposed in a zigzag pattern in the Y-direction. For example, the first electrode structures 170 may be disposed in a honeycomb structure. However, the arrangement of the lower electrode structures 170 is not limited thereto.

Referring to FIGS. 2A to 2C, the lower electrode structures 170 may have a pillar shape. The lower electrode structures 170 may have a cylindrical shape of which a horizontal width, for example, a radius, may change in the Z-direction. For example, radii r1, r2, and r3 of the lower electrode structures 170 may decrease toward an upper surface of the substrate 101 (e.g., in the Z direction).

The supporter structures SS1, SS2, and SS3 may include a lower supporter structure SS3, an intermediate supporter structure SS2 on the lower supporter structure SS3, and an upper supporter structure SS1 on the intermediate supporter structure SS2. The lower supporter structure SS3, the intermediate supporter structure SS2, and the upper supporter structure SS1 may be spaced apart from the substrate 101 in order in a direction perpendicular to the upper surface of the substrate 101. The supporter structures SS1, SS2, and SS3 may support the lower electrode structures 170 having a high aspect ratio. Each of the support structures SS1, SS2, and SS3 may include, for example, at least one of silicon nitride, silicon oxynitride, or similar materials.

Referring to FIGS. 2A and 2B, the upper supporter structure SS1 may include upper supporter patterns SP1 connecting the upper region UR of the lower electrode structures 170 to each other. The upper supporter patterns SP1 may be spaced apart from each other in the horizontal direction.

Each of the upper supporter patterns SP1 may surround at least one first lower electrode structure 170_1 of the lower electrode structures 170 and may contact with side surfaces of the plurality of second lower electrode structures 1702 adjacent to the at least one first lower electrode structure 170_1. For example, referring to FIG. 2A, the upper supporter patterns SP1 may surround the first lower electrode structure 170_1 and may be disposed to be in contact with at least a portion of the side surfaces of the six second lower electrode structures 170_2s closest to the first lower electrode structure 170_1.

A distance between centers of upper supporter patterns SP1 adjacent to each other in a horizontal direction may be defined as a first distance L1. In a different point of view, the first distance L1 may be defined as a distance, for example a minimum horizontal distance, between conceptual vertical axes X1 penetrating a center of the first lower electrode structures 170_1 in the Z-direction. In some example embodiments, the Z-direction may be perpendicular to the horizontal directions (e.g., X-direction and Y-direction). Here, the conceptual vertical axes X1 may be defined as being arranged in the third horizontal direction D3 intersecting the first horizontal direction D1 and the second horizontal direction D2. The first distance L1 may be configured to be 76 nm or more, for example, 76 nm to 120 nm, or 76 nm to 110 nm, or 76 nm to 100 nm. In some example embodiments, the semiconductor device 100 may include a supporter pattern surrounding at least one first lower electrode structure 170_1 and in contact with side surfaces of the plurality of second lower electrode structures 170_2 adjacent to the at least one first lower electrode structure 170_1, such that limitations of the pitch, for example a minimum pitch, between the supporter patterns may be addressed in a patterning process.

Referring to FIG. 2A, the external side surface SP1_s of the upper supporter pattern SP1 may have an outwardly curved shape between the second lower electrode structures 170_2. For example, when the external side surfaces SP1_s of the upper supporter pattern SP1 are extended in a conceptual curve and connected to each other, the upper supporter pattern SP1 may be interpreted as having a circular shape. For example, the external side surfaces SP1_s of the upper supporter pattern SP1 may have a convex shape in a direction away from a center of the first upper supporter pattern.

Referring to FIGS. 2B and 2C, the intermediate supporter structure SS2 may include intermediate supporter patterns SP2 connecting the intermediate region MR of the lower electrode structures 170 to each other. Here, the intermediate region MR may be a term referring to a region disposed below the upper region UR, and may not be limited to a specific region. The intermediate supporter patterns SP2 may be spaced apart from each other in the horizontal direction.

The intermediate supporter patterns SP2 may be aligned with the upper supporter patterns SP1 in a vertical direction, for example, the Z-direction. Specifically, centers of the intermediate supporter patterns SP2 may be aligned on the same vertical axis X1 as centers of the upper supporter patterns SP1, respectively.

Accordingly, the intermediate supporter patterns SP2 may surround the first lower electrode structure 170_1 and may contact with at least a portion of the side surfaces of the six second lower electrode structures 170_2 closest to the first lower electrode structure 170_1.

Referring to FIG. 2C, the external side surface SP2_s of the intermediate supporter pattern SP2 may have an outwardly curved shape between the second lower electrode structures 170_2. For example, when the external side surfaces SP2_s of the intermediate supporter pattern SP2 are extended in a conceptual curve and connected to each other, the intermediate supporter pattern SP2 may be interpreted as having a circular shape.

Referring to FIGS. 2B and 2C, the lower supporter structure SS3 may include lower supporter patterns SP3 connecting the lower region LR of the lower electrode structures 170 to each other. Here, the lower region LR may be a term referring to a region disposed below the intermediate region MR, and may not be limited to a specific region. The lower supporter patterns SP3 may be spaced apart from each other in the horizontal direction.

The lower supporter patterns SP3 may be aligned with the intermediate supporter patterns SP2 in a vertical direction, for example, in the Z-direction. Specifically, centers of the lower supporter patterns SP3 may be aligned on the same vertical axis X1 as centers of the intermediate supporter patterns SP2. Accordingly, the centers of the lower supporter patterns SP3 may be aligned on the vertical axis X1, which may also be the same as the centers of the upper supporter patterns SP1.

Accordingly, the lower supporter patterns SP3 may surround the first lower electrode structure 170_1 and may contact with at least a portion of the side surfaces of the six second lower electrode structures 170_2 closest to the first lower electrode structure 170_1, respectively.

Referring to FIG. 2C, the external side surface SP3_s of the lower supporter pattern SP3 may have an outwardly curved shape between the second lower electrode structures 170_2. For example, when the external side surfaces SP3_s of the lower supporter pattern SP3 are extended in a conceptual curve and connected to each other, the upper supporter pattern SP3 may be interpreted as having a circular shape.

Referring to FIGS. 2A to 2C, in the upper, intermediate, and lower regions UR, MR, and LR, distances from the centers of the first lower electrode structure 170_1 to the external side surfaces SP1_s, SP2_s, and SP3_s of the supporter pattern may be different. In a different point of view, in the upper, intermediate, and lower regions UR, MR, and LR, widths, for example maximum horizontal widths, of the supporter patterns may be different.

In the upper region UR, a distance from a center of the first lower electrode structure 170_1 to the external side surface SP1_s of the upper supporter pattern SP1 may be defined as a first radius R1. The first radius R1 may increase toward an upper surface of the substrate 101 in the upper region UR.

In the intermediate region MR, a distance from a center of the first lower electrode structure 170_1 to the external side surface SP2_s of the intermediate supporter pattern SP2 may be defined as a second radius R2. The second radius R2 in the intermediate region MR may be greater than the first radius R1 in the upper region UR. Accordingly, a ratio of an external side surface 170_2s in contact with the intermediate supporter pattern SP2 among the external side surfaces 170_2s of the second lower electrode structures 170_2 in the intermediate region MR may be greater than that in the upper region UR. For example, the ratio of external side surface 170_2s in contact with the intermediate supporter pattern SP2 in the intermediate region MR to the total surface area of the second lower electrode structures 170_2 in the intermediate region MR may be greater than the ratio of external side surface 170_2s in contact with the upper supporter pattern SP1 in the upper region UR to the total surface area of the second lower electrodes structures 170_2 in the upper region UR. The second radius R2 may increase toward the upper surface of the substrate 101 in the intermediate region MR.

In the lower region LR, a distance from a center of the first lower electrode structure 170_1 to the external side surface SP3_s of the lower supporter pattern SP3 may be defined as a third radius R3. The third radius R3 in the lower region LR may be greater than the second radius R2 in the intermediate region MR. Accordingly, a ratio of the external side surface 170_2s of the second lower electrode structures 170_2 in the lower region LR and the external side surface in contact with the lower supporter pattern SP3 may be greater than that in the intermediate region MR. For example, the ratio of external side surface 170_2s in contact with the lower supporter pattern SP3 in the lower region LR to the total surface area of the second lower electrode structures 170_2 in the lower region LR may be greater than the ratio of external side surface 170_2s in contact with the upper supporter pattern SP2 in the intermediate region MR to the total surface area of the second lower electrodes structures 170_2 in the intermediate region MR. The third radius R3 may increase toward the upper surface of the substrate 101 in the lower region LR.

In other words, in each of the upper, intermediate, and lower regions UR, MR, and LR, horizontal widths of the supporter patterns may increase toward the upper surface of the substrate 101. Also, a width, for example a maximum horizontal width, of the supporter pattern in upper region UR may be greater than a width, for example a maximum horizontal width, of the supporter pattern in the intermediate region UR, and a width, for example a maximum horizontal width, of the supporter pattern in the intermediate region UR may be greater than a width, for example a maximum horizontal width, of the supporter pattern in the lower region LR.

Referring to FIGS. 2A to 2C, in the upper, intermediate, and lower regions UR, MR, and LR, the angle formed by tangents of the external side surfaces SP1_s, SP2_s, and SP3_s of the upper supporter pattern and a tangent of the corresponding external side surface 170_2s of the second lower electrode structure 170_2 may be different.

In the upper region UR, at a point at which the upper supporter pattern SP1 and the second lower electrode structure 170_2 are in contact with, the angle formed by the tangent of the external side surface SP1_s of the upper supporter pattern SP1 and the tangent of the external side surface 170_2s of the second lower electrode structure 170_2 may be defined as the first angle θ1. The first angle θ1 may increase toward the upper surface of the substrate 101 in the upper region UR.

In the intermediate region MR, at the point at which the intermediate supporter pattern SP2 and the second lower electrode structure 170_2 are in contact with each other, the angle formed by the tangent of the external side surface SP2_s of the intermediate supporter pattern SP2 and the tangent of the external side surface 170_2s of the second lower electrode structure 170_2 may be defined as the second angle θ2. The second angle θ2 in the intermediate region MR may be greater than the first angle θ1 in the upper region UR. The second angle θ2 may increase toward the upper surface of the substrate 101 in the intermediate region MR.

In the lower region LR, at a point at which the lower supporter pattern SP3 and the second lower electrode structure 170_2 are in contact with each other, the angle formed by the tangent of the external side surface SP3_s of the lower supporter pattern SP3 and the tangent of the external side surface 170_2s of the second lower electrode structure 170_2 may be defined as the third angle θ3. The third angle θ3 in the lower region LR may be greater than the second angle θ2 in the intermediate region MR. The third angle θ2 may increase toward the upper surface of the substrate 101 in the lower region LR.

Referring to FIGS. 2A to 2C, in the upper, intermediate, and lower regions UR, MR, and LR, the open patterns OP1, OP2, and OP3 may be defined.

In the upper region UR, the upper open pattern OP1 may be defined by the upper supporter patterns SP1 and the plurality of second lower electrode structures 170_2. Specifically, the upper open pattern OP1 may be defined by the external side surface SP1_s of the upper supporter patterns SP1 and the external side surface 170_2s of the second lower electrode structures 170_2. The upper open pattern OP1 may extend in the horizontal direction.

In the intermediate region MR, the intermediate open pattern OP2 may be defined by the intermediate supporter patterns SP2 and the plurality of second lower electrode structures 170_2. Specifically, the intermediate open pattern OP2 may be defined by the external side surface SP2_s of the intermediate supporter patterns SP2 and the external side surface 170_2s of the second lower electrode structures 170_2. The intermediate open pattern OP2 may extend in the horizontal direction.

In the lower region LR, the lower open pattern OP3 may be defined by the lower supporter patterns SP3 and the plurality of second lower electrode structures 170_2. Specifically, the lower open pattern OP3 may be defined by the external side surface SP3_s of the lower supporter patterns SP3 and the external side surface 170_2s of the second lower electrode structures 170_2. The lower open pattern OP3 may extend in the horizontal direction.

Referring to FIGS. 1 and 2A together, in the upper region UR of the cell region CA, a ratio of the horizontal area of the upper open pattern OP1 to the sum of the horizontal area of the lower electrode structure 170, the upper supporter patterns SP1, and the upper open pattern OP1 may be defined as an open pattern ratio OR. According to some example embodiments, the open pattern ratio OR may be 30% or more, for example, 30% to 45%, 35% to 40%, or 38% to 40%. In some example embodiments, an open pattern ratio OR corresponding to the intermediate open pattern OP2 may be less than the open pattern ratio OR corresponding to the upper open pattern OP1 and an open pattern ratio OR corresponding to the lower open pattern OP3 may be less than the open pattern ratio OR corresponding to the intermediate open patter OP2.

The open patterns OP1, OP2, and OP3 may be configured as regions in which the upper electrode structure 174 is disposed.

Referring to FIGS. 2A to 2C, in the upper, intermediate, and lower regions UR, MR, and LR, a distance, for example a minimum horizontal distance, between the supporter patterns adjacent to each other in the horizontal direction may be different.

In the upper region UR, a first distance, for example a minimum horizontal distance, D1 between the upper supporter patterns SP1 adjacent to the horizontal direction may be defined as a distance obtained by subtracting twice the size of the first radius R1 from the first distance L1. D1=L1-2·R1.

In the intermediate region MR, the second distance, for example a minimum horizontal distance, D2 between the intermediate supporter patterns SP2 adjacent to the horizontal direction may be defined as a distance obtained by subtracting twice the size of the second radius R2 from the first distance L1. D2=L1-2·R2.

In the lower region LR, a third distance, for example a minimum horizontal distance, D3 between the lower supporter patterns SP3 adjacent to the horizontal direction may be defined as a distance obtained by subtracting twice the size of the third radius R3 from the first distance L1. D3=L1-2·R3.

As described above, the third radius R3 may be greater than the second radius R2, such that the third minimum horizontal distance D3 may be smaller than the second minimum horizontal distance D2. Similarly, the second radius R2 may be greater than the first radius R1, such that the second minimum horizontal distance D2 may be smaller than the first minimum horizontal distance D1.

The dielectric layer 172 may cover a side surface and an upper surface of each of the lower electrode structures 170 on a surface of the lower electrode structures 170. The dielectric layer 172 may be disposed between the lower electrode structures 170 and the upper electrode structures 174. The dielectric layer 172 may cover upper and lower surfaces of the support structures SS1, SS2, and SS3. The dielectric layer 172 may cover the upper surface of the etch stop layer 168. In the plan diagram, the first lower electrode structures 170_1 may not be covered by the dielectric layer 172 (see FIGS. 2A and 2C).

The dielectric layer 172 may include a high dielectric material, silicon oxide, silicon nitride, or a combination thereof. According to some example embodiments, the dielectric layer 172 may include oxide, nitride, silicide, oxynitride, or silicooxynitride titanium (Ti), tantalum (Ta), hafnium (Hf), aluminum (Al), zirconium (Zr), and/or lanthanum (La) doped with fluorine (F) or combinations of thereof.

The upper electrode structure 174 may be disposed on the dielectric layer 172. The upper electrode structure 174 may fill the space between the plurality of lower electrode structures 170, the space between the upper supporter patterns SP1 (or “upper open pattern OP1” portion), the space between the intermediate supporter patterns SP2 (or “intermediate open pattern OP2” portion), and the space between lower supporter pattern SP3 (or “lower open pattern OP3” portion). Referring to FIGS. 2A and 2C, when viewed in the horizontal direction, the upper electrode structure 174 may be disposed in a honeycomb structure. However, the arrangement of the upper electrode structure 174 is not limited thereto.

In some example embodiments, the dielectric layer 172 and the upper electrode structure 174 may extend further into the interface region IA (not illustrated). The upper electrode structure 174 may include a conductive material.

The upper electrode structure 174 may include a single layer or a plurality of layers.

In some example embodiments, the upper electrode structure 174 may be in contact, for example direct contact, with the dielectric layer 172 and may include a first material layer formed along the dielectric layer 172 and a second material layer covering the first material layer. The first material layer may include a doped semiconductor, a metal, a conductive metal nitride, a metal-semiconductor compound, a conductive metal oxide, or a combination thereof. The second material layer may include a silicon material or a silicon-germanium material. For example, the second material layer may include a doped silicon material or a doped silicon-germanium material.

In some example embodiments, the upper electrode structure 174 may further include a protective material layer which may prevent or reduce in likelihood natural oxidation of the upper electrode structure 174 and oxidation by the dielectric layer 172. For example, the protective material layer may be covered by the first material layer and may be in contact, for example, direct contact, with the dielectric layer 172. The protective material layer may include at least one of metal, metal-silicon oxide, metal-silicon nitride, or metal-silicon oxynitride.

The semiconductor device 100 may further include an upper interlayer insulating layer 188 covering the data storage structure CAP. The upper interlayer insulating layer 188 may include silicon oxide, silicon nitride, silicon oxynitride, or a combination thereof. In some example embodiments, the upper interlayer insulating layer 188 may include silicon oxide. An upper surface of the upper interlayer insulating layer 188 may be flat, for example, parallel to the upper surface of the substrate 101.

The semiconductor device 100 may further include a cell contact plug CCP, an interlayer insulating layer ILD, and a plurality of upper contact plugs 92 disposed on the data storage structure CAP. The cell contact plug CCP may penetrate the upper interlayer insulating layer 188 and may be connected to the data storage structure CAP. For example, the cell contact plug CCP may penetrate the upper interlayer insulating layer 188 and may be connected to the upper electrode structure 174. A lower surface of the cell contact plug CCP may be disposed on a level lower than a level of an upper surface of the upper electrode structure 174. An upper surface of the cell contact plug CCP may be coplanar with each other. The cell contact plug CCP may include a barrier layer CCPa and a conductive layer CCPb on the barrier layer CCPa. A side surface of the cell contact plug CCP may be in contact with the upper interlayer insulating layer 188.

The interlayer insulating layer ILD may be disposed on the upper interlayer insulating layer 188. The interlayer insulating layer ILD may cover the cell contact plug CCP and the upper interlayer insulating layer 188. The interlayer insulating layer ILD may include silicon oxide.

The plurality of upper contact plugs 92 may penetrate the interlayer insulating layer ILD, and at least one of the plurality of upper contact plugs 92 may be connected to the cell contact plug CCP. The plurality of upper contact plugs 92 may include a barrier layer 90 and a conductive layer 91 on the barrier layer 90. Lower surfaces of the plurality of upper contact plugs 92 may be flat, for example, parallel to the upper surface of the substrate 101. The lower surfaces of the plurality of upper contact plugs 92 may be disposed on the same level.

The barrier layer CCPa and the barrier layer 90 may include a metal nitride such as titanium nitride (TiN). The conductive layer CCPb and the conductive layer 91 may include a conductive material such as tungsten (W) and/or tungsten nitride (WN).

Referring to FIGS. 1 and 2B, the semiconductor device 100 may further include device an isolation layer 10, a second active region ACT2, a first peripheral impurity region 5a and a second peripheral impurity region 5b in the peripheral circuit region PA. The device isolation layer 10 may be configured as an insulating layer extending upward from the upper surface of the substrate 101 and may define the second active region ACT2. The first peripheral impurity region 5a and the second peripheral impurity region 5b may be spaced apart from each other with the peripheral gate structure 40 therebetween.

The device isolation layer 10 may include silicon oxide, silicon nitride, silicon oxynitride, or a combination thereof, and may include a single layer or a plurality of layers. The first and second peripheral impurity regions 5a and 5b may work as source/drain regions of a transistor including the peripheral gate structure 40. The first and second peripheral impurity regions 5a and 5b may include impurities having a conductivity-type opposite to that of the substrate 101.

The semiconductor device 100 may further include a peripheral gate dielectric layer 30 and a peripheral gate structure 40 disposed on the substrate 101 in the peripheral circuit region PA. The peripheral gate structure 40 may have a structure and a material similar to those of the bitline BL.

The peripheral gate structure 40 may include a first conductive pattern 41, a second conductive pattern 42, and a third conductive pattern 43 stacked in order on the peripheral gate dielectric layer 30 of the substrate 101. The peripheral gate dielectric layer 120 may include silicon oxide, silicon nitride, or a high-x material. The high-x material may refer to a dielectric material having a higher dielectric constant than that of silicon oxide. The first conductive pattern 41, the second conductive pattern 42 and the third conductive pattern 43 of the peripheral gate structure 40 may include the same materials as those of the first conductive pattern 141, the second conductive pattern 142 and the third conductive pattern 143 of the bitline BL, respectively. The first peripheral capping pattern 46 may be disposed on the peripheral gate structure 40. The first peripheral capping pattern 46 may include the same material as that of the first capping pattern 146 of the bitline capping pattern BC.

The semiconductor device 100 may further include a peripheral gate spacer SSP, a second peripheral capping pattern 47, an interlayer insulating layer 45 and a third peripheral capping pattern 48 in the peripheral circuit region PA. The peripheral gate spacer SSP may cover a side surface of the peripheral gate structure 40. For example, the peripheral gate spacers SSP may be spaced apart from each other with the peripheral gate structure 40 therebetween, and the first conductive pattern 41, the second conductive pattern 42, the third conductive pattern 43 and the first peripheral capping pattern 46 may cover the side surface.

The second peripheral capping pattern 47 may cover the substrate 101, the peripheral gate spacer SSP, and the peripheral gate structure 40, and may be formed conformally. The interlayer insulating layer 45 may partially cover the second peripheral capping pattern 47. An upper surface of the interlayer insulating layer 45 may be coplanar with each other. The third peripheral capping pattern 48 may cover the insulating layer 45 and the second peripheral capping pattern 47.

The second peripheral capping pattern 47 and the third peripheral capping pattern 48 may include the same material as those of the second capping pattern 147 and the third capping pattern 148 of the bitline capping pattern BC, respectively, and may include, for example, silicon nitride. The interlayer insulating layer 45 may include silicon oxide.

The semiconductor device 100 may further include a peripheral plug 63 and a peripheral interconnection 60 electrically connected to the first and second peripheral impurity regions 5a and 5b in the peripheral circuit region PA. The peripheral plugs 63 may penetrate the insulating layer 45, may be disposed adjacent to the peripheral gate structure 40 and may be in contact with the first and second peripheral impurity regions 5a and 5b. The peripheral interconnection 60 may be disposed on the third peripheral capping pattern 48 and the peripheral plug 63 and may extend in the horizontal direction. In some example embodiments, the peripheral interconnection 60 may be integrated with the peripheral plug 63. For example, the peripheral interconnection 60 may include a barrier layer 61 and a conductive layer 62, and the barrier layer 61 and the conductive layer 62 may extend vertically downwardly and may form a peripheral plug 63. In some example embodiments, the peripheral interconnection 60 may not be integrated with peripheral plug 63.

The semiconductor device 100 may further include an insulating pattern 65 disposed between the peripheral interconnections 60. The insulating patterns 65 may spatially isolate the peripheral interconnections 60 and may electrically insulate the peripheral interconnections 60 from each other.

The semiconductor device 100 may further include an etch stop layer 68 disposed on the peripheral interconnections 60. The etch stop layer 68 may be integrated with the etch stop layer 168. For example, the etch stop layer 68 may be formed by extending the etch stop layer 168 to the peripheral circuit region PA.

The semiconductor device 100 may further include a peripheral contact plug PCP and an upper contact plug 95 disposed on the peripheral interconnections 60. The peripheral contact plug PCP may penetrate the upper interlayer insulating layer 188, the lower interlayer insulating layer 186 and the etch stop layer 68 and may be in contact with one of the peripheral interconnections 60. The peripheral contact plug PCP may be electrically connected to the first peripheral impurity region 5a or the second peripheral impurity region 5b through the peripheral interconnection 60 and the peripheral plug 63. An upper surface of the peripheral contact plug PCP may be coplanar with each other. The peripheral contact plug PCP may include a barrier layer PCPa and a conductive layer PCPb on the barrier layer PCPa.

The upper contact plug 95 may penetrate the interlayer insulating layer ILD, and the upper contact plug 95 may be connected to the peripheral contact plug PCP. The upper contact plug 95 may include a barrier layer 93 and a conductive layer 94 on the barrier layer 93. A lower surface of the upper contact plug 95 may be flat, for example, parallel to an upper surface of the substrate 101. A lower surface of the upper contact plug 95 may be disposed on the same level as lower surfaces of the plurality of upper contact plugs 92.

The barrier layer PCPa and the barrier layer 93 may include a metal nitride such as titanium nitride (TiN). The conductive layer PCPb and the conductive layer 94 may include a conductive material such as tungsten (W) and/or tungsten nitride (WN).

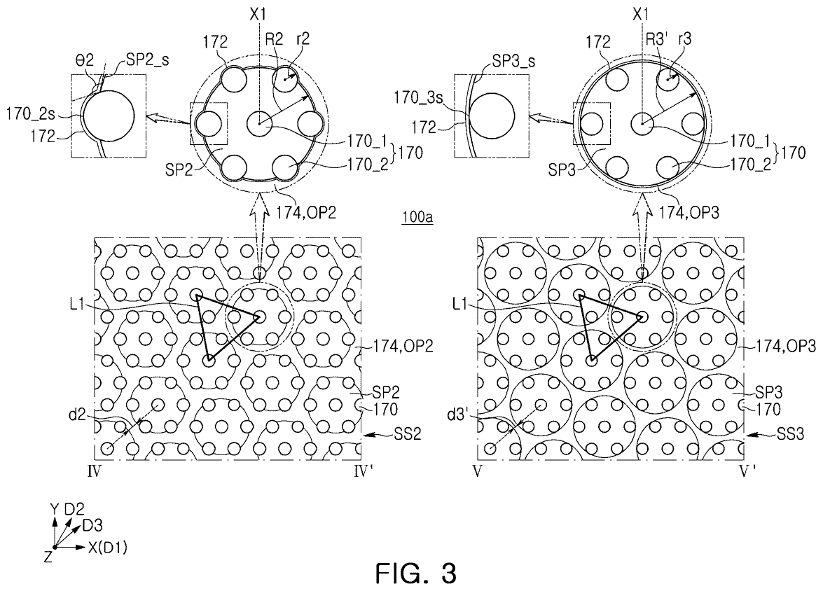

FIG. 3 is a plan diagram illustrating a semiconductor device according to some example embodiments.

Referring to FIG. 3, a semiconductor device 100a according to some example embodiments may be the same or similar to the example described with reference to FIGS. 1 to 2C other than a configuration in which an circumferential surface of the second lower electrode structures 170_2 is in contact with an internal side surface of the lower supporter pattern SP3.

Referring to FIG. 3, the lower supporter pattern SP3 may surround the first lower electrode structure 170_1 and also a plurality of second lower electrode structures 170_2. Accordingly, in the plan diagram, the external side surface SP3_s of the lower supporter pattern SP3 may have a circular shape having a third radius R3′.

The third radius R3′ may be greater than the third radius R3 described with reference to FIG. 2C, and accordingly, the third distance, for example a minimum horizontal distance, D3′ may also be smaller than the minimum horizontal distance D3 described with reference to FIG. 2C.

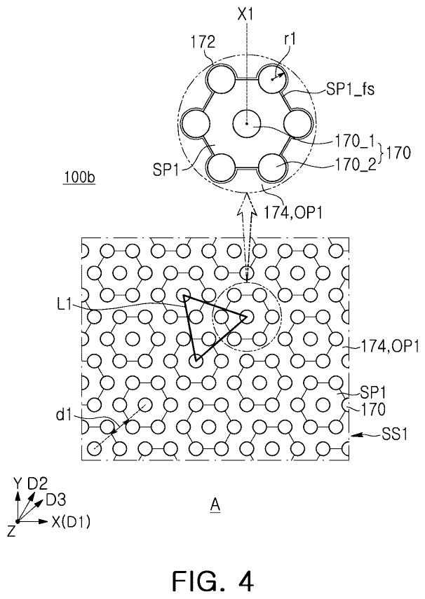

FIG. 4 is an enlarged diagram illustrating a portion of a semiconductor device according to some example embodiments.

Referring to FIG. 4, a semiconductor device 100b according to some example embodiments may be the same as or similar to the example described with reference to FIGS. 1 to 3, other than the configuration in which the external side surface SP1_fs of the upper supporter pattern SP1 has a flat surface.

Referring to FIG. 4, when the external side surfaces SP1_fs of the upper supporter pattern SP1 are extended by a conceptual plurality of linear lines and connected to each other, the upper supporter pattern SP1 may be interpreted as having a regular hexagonal shape. Similar to the example described with reference to FIGS. 2A to 2C, a width, for example a maximum horizontal width, of the supporter pattern may be greater in the lower region MR.

In some example embodiments, an external side surface of the supporter pattern may not have a flat surface in the intermediate region MR and/or the lower region LR, differently in the upper region UR. For example, in the intermediate region MR, the external side surface of the intermediate supporter pattern may have an outwardly curved shape as in the example described with reference to FIG. 2C. In this case, in the lower region LR, the external side surface of the lower supporter pattern may also have an outwardly curved shape as in the example described with reference to FIG. 2c.

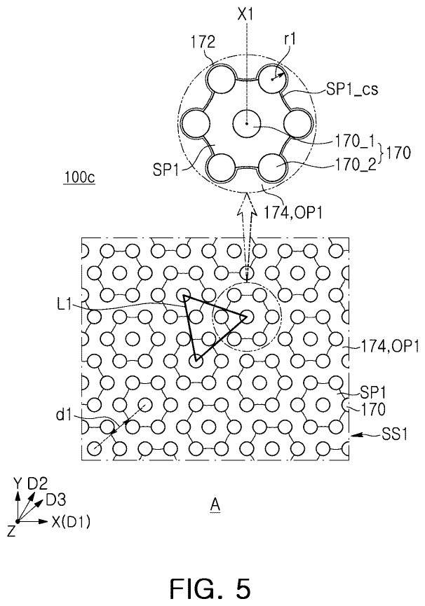

FIG. 5 is an enlarged diagram illustrating a portion of a semiconductor device according to example embodiments.

Referring to FIG. 5, a semiconductor device 100c according to some example embodiments may be the same as or similar to the example described with reference to FIGS. 1 to 4, other than the configuration in which the external side surface SP1_cs of the upper supporter pattern SP1 has a concave surface.

Referring to FIG. 5, the external side surfaces SP1_cs of the upper supporter pattern SP1 may have a concave shape inwardly. For example, the external side surfaces of SP1_cs of the upper supporter pattern SP1 may have a convex shape in a direction toward a center of the first upper supporter pattern 170_1.

In the example embodiment, a curvature of the external side surface of the supporter pattern may decrease toward the lower region LR. In other words, the degree of curvature of the external side surface of the supporter pattern may decrease toward the lower region LR. For example, the curvature in the intermediate region MR may be smaller than the curvature in the upper region UR, and the curvature in the lower region LR may be smaller than the curvature in the intermediate region MR.

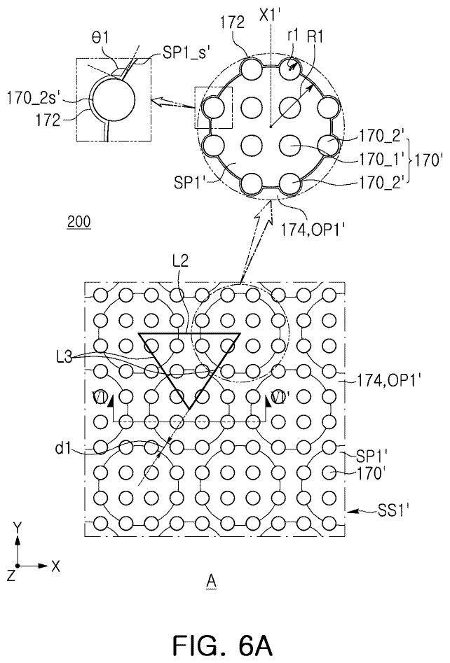

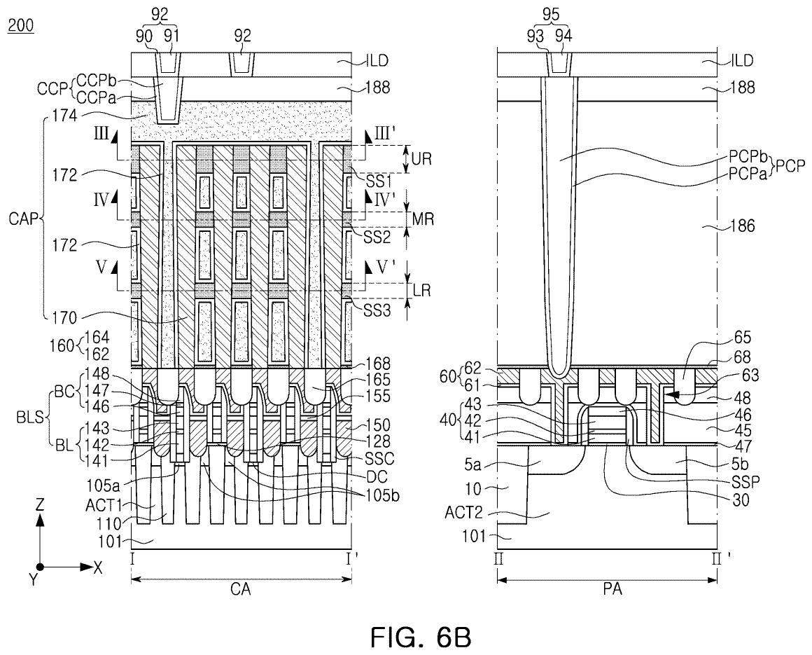

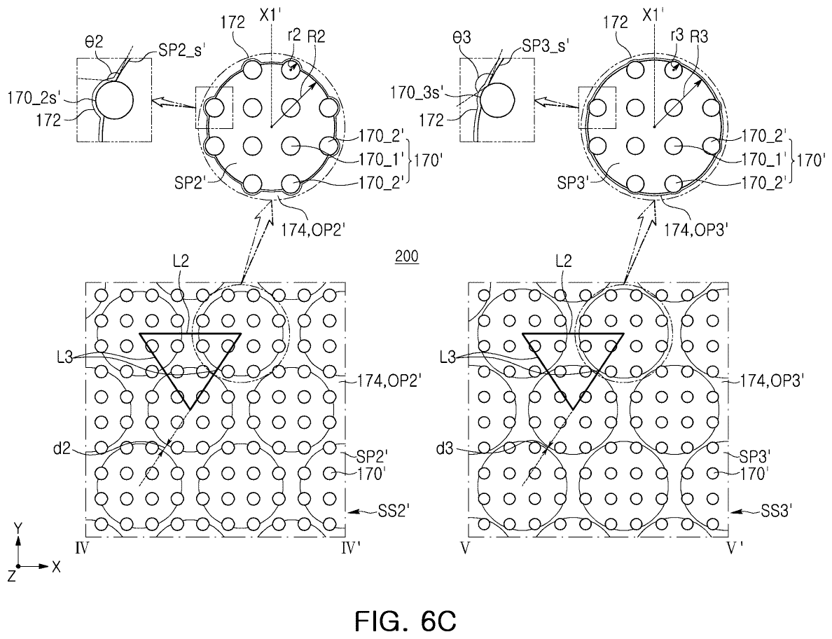

FIG. 6A is an enlarged diagram illustrating region “A” of the semiconductor device illustrated in FIG. 1.

FIG. 6B is a vertical cross-sectional diagram illustrating the semiconductor device illustrated in FIG. 6A taken along line I-I′ and the semiconductor device illustrated in FIG. 1 taken along line II-II′. FIG. 6A is a plan diagram illustrating the semiconductor device illustrated in FIG. 6B taken along line III-III′.

FIG. 6C is a plan diagram illustrating the semiconductor device illustrated in FIG. 6B taken along lines IV-IV′ and V-V′.

Referring to FIGS. 6A to 6C, a semiconductor device 200 according to some example embodiments may be the same or similar to the example described with reference to FIGS. 1 to 5 other than the configuration in which lower electrode structures 170′ spaced apart from each other by a predetermined distance in the first horizontal direction X and arranged in the second horizontal direction Y perpendicular to the first horizontal direction are included.

In a different point of view, the lower electrode structures 170′ may be disposed in a grid structure, each having a right-angled shape.

Referring to FIGS. 6A and 6B, the upper supporter structure SS1′ may include upper supporter patterns SP1′ connecting the upper region UR of the lower electrode structures 170′ to each other. The upper supporter patterns SP1′ may be spaced apart from each other in the horizontal direction.

The upper supporter patterns SP1′ may be surround at least one first lower electrode structure 170_1′ of the lower electrode structures 170′ and may contact with a side surface of the plurality of second lower electrode structures adjacent to the at least one first lower electrode structure 170_1′. For example, referring to FIG. 6A, each of the upper supporter patterns SP1 may surround four first lower electrode structures 170_1′ most adjacent to each other and may be disposed to be in contact with at least a portion of side surfaces of the second lower electrode structures 170_2′ closest to the first lower electrode structures 170_1′. In the plan diagram viewed from above, the second lower electrode structures 170_2′ may refer to eight second lower electrode structures disposed on an external side of the first lower electrode structures 170_1′.

A distance between the centers of upper supporter patterns SP1′ adjacent to each other in the horizontal direction, for example, the X-direction, may be defined as a second distance L2. In a different point of view, the second distance L2 may be defined as a horizontal distance in the X-direction between conceptual vertical axes X1′ penetrating a center of mass of the four first lower electrode structures 170_1′ in the Z-direction. The second distance L2 may be configured to be 95 nm or more, for example, 95 nm to 135 nm, or 95 nm to 120 nm, or 95 nm to 110 nm.

A distance between centers of the upper supporter patterns SP1′ adjacent to each other in the third horizontal direction intersecting the X and Y-directions may be defined as a third distance L3. In a different point of view, the third distance L3 may be defined as a horizontal distance in the third horizontal direction between conceptual vertical axes X1′ penetrating a center of mass of the four first lower electrode structures 170_1′ in the Z-direction. The third distance L3 may be smaller than the second distance L2. For example, the third distance L3 may be smaller than the second distance L2 by 10 nm or less, for example, in the range of 5 nm to 10 nm.

Referring to FIG. 6A, the external side surface SP1_s′ of the upper supporter pattern SP1′ may have an outwardly curved shape between the second lower electrode structures 170_2′. For example, when the external side surfaces SP1_s′ of the upper supporter pattern SP1′ are extended in a conceptual curve and connected to each other, the upper supporter pattern SP1′ may be interpreted as having a circular shape.

Referring to FIGS. 6B and 6C, the intermediate supporter structure SS2′ may include intermediate supporter patterns SP2′ connecting the intermediate region MR of the lower electrode structures 170′ to each other. Here, the intermediate region MR may be a term referring to a region disposed below the upper region UR, and may not be limited to a specific region. The intermediate supporter patterns SP2′ may be spaced apart from each other in the horizontal direction.

The intermediate supporter patterns SP2′ may be aligned with the upper supporter patterns SP1′ in a vertical direction, for example, in the Z-direction. Specifically, centers of the intermediate supporter patterns SP2′ may be aligned on the same vertical axis X1′ as centers of the upper supporter patterns SP1′.

Accordingly, the intermediate supporter patterns SP2′ may surround the four first lower electrode structures 170_1′ and may contact with at least a portion of side surfaces of a plurality of second lower electrode structures 170_2′ closest to the first lower electrode structures 170_1′.

Referring to FIG. 6C, the external side surface SP2_s′ of the intermediate supporter pattern SP2′ may have an outwardly curved shape between the second lower electrode structures 170_2′. For example, when the external side surfaces SP2_s′ of the intermediate supporter pattern SP2′ are connected to each other in a conceptual curve, the intermediate supporter pattern SP2′ may be interpreted as having a circular shape.

Referring to FIGS. 6B and 6C, the lower supporter structure SS3′ may include lower supporter patterns SP3′ connecting the lower region LR of the lower electrode structures 170′ to each other. Here, the lower region LR may be a term referring to a region disposed below the intermediate region MR, and may not be limited to a specific region. The lower supporter patterns SP3′ may be spaced apart from each other in the horizontal direction.

The lower supporter patterns SP3′ may be aligned with the intermediate supporter patterns SP2′ in a vertical direction, for example, in the Z-direction. Specifically, centers of the lower supporter patterns SP3′ may be aligned on the same vertical axis X1′ as centers of the intermediate supporter patterns SP2′. Accordingly, the centers of the lower supporter patterns SP3′ may be aligned on the vertical axis X1′, which may also be the same as centers of the upper supporter patterns SP1′.

Accordingly, the lower supporter patterns SP3′ may also surround the four first lower electrode structures 170_1′ and may contact with at least a portion of side surfaces of a plurality of second lower electrode structures 170_2′ closest to the first lower electrode structures 170_1′.

Referring to FIG. 6C, the external side surface SP3_s′ of the lower supporter pattern SP3′ may have an outwardly curved shape between the second lower electrode structures 170_2′. For example, when the external side surfaces SP3_s′ of lower supporter pattern SP3′ are connected to each other in a conceptual curve, the upper supporter pattern SP3′ may be interpreted as having a circular shape.

Referring to FIGS. 6A to 6C, in the upper, intermediate, and the lower regions UR, MR, and LR, distances from the vertical axis X1′ to the external side surfaces SP1_s′, SP2_s′, and SP3_s′ of the supporter pattern may be different.

In the upper region UR, a distance from the vertical axis X1′ to the external side surface SP1_s′ of the upper supporter pattern SP1 may be defined as a first radius R1. The first radius R1 may increase toward an upper surface of the substrate 101 in the upper region UR.

In the intermediate region MR, a distance from the vertical axis X1′ to the external side surface SP2_s′ of the intermediate supporter pattern SP2′ may be defined as a second radius R2. The second radius R2 in the intermediate region MR may be greater than the first radius R1 in the upper region UR. Accordingly, a ratio of an external side surface in contact with intermediate supporter pattern SP2′ among the external side surface 170_2s′ of the second lower electrode structures 170_2′ in the intermediate region MR may be greater than that in the upper region UR. For example, the ratio of external side surface 170_2s′ in contact with the intermediate supporter pattern SP2′ in the intermediate region MR to the total surface area of the second lower electrode structures 170_2′ in the intermediate region MR may be greater than the ratio of external side surface 170_2s′ in contact with the upper supporter pattern SP1 in the upper region UR to the total surface area of the second lower electrodes structures 170_2′ in the upper region UR. The second radius R2 may increase toward the upper surface of the substrate 101 in the intermediate region MR.

In the lower region LR, a distance from the vertical axis X1′ to the external side surface SP3_s′ of the lower supporter pattern SP3′ may be defined as a third radius R3. The third radius R3 in the lower region LR may be greater than the second radius R2 in the intermediate region MR. Accordingly, a ratio of the external side surface in contact with the lower supporter pattern SP3 among the external side surface 170_2s′ of the second lower electrode structures 170_2′ in the lower region LR may be greater than that in the intermediate region MR. For example, the ratio of external side surface 170_2s′ in contact with the lower supporter pattern SP3′ in the lower region LR to the total surface area of the second lower electrode structures 170_2′ in the lower region LR may be greater than the ratio of external side surface 170_2s′ in contact with the intermediate supporter pattern SP2 in the intermediate region MR to the total surface area of the second lower electrodes structures 170_2′ in the intermediate region MR. The third radius R3 may increase toward the upper surface of the substrate 101 in the lower region LR.

Referring to FIGS. 6A to 6C, in the upper, intermediate, and lower regions UR, MR, and LR, angles formed by tangents of the external side surfaces SP1_s′, SP2_s′, and SP3_s′ of the upper supporter pattern and a tangent of the external side surface 170_2s′ of the corresponding second lower electrode structure 170_2′ may be different.

In the upper region UR, at the point at which the upper supporter pattern SP1′ and the second lower electrode structure 170_2′ are in contact with each other, the angle formed by the tangent of the external side surface SP1_s′ of the upper supporter pattern SP1′ and the tangent of the external side surface 170_2s′ of the second lower electrode structure 170_2′ may be defined as a first angle θ1. The first angle θ1 may increase toward the upper surface of the substrate 101 in the upper region UR.

In the intermediate region MR, at the point at which the intermediate supporter pattern SP2′ and the second lower electrode structure 170_2′ are in contact with each other, the angle formed by the tangent of the external side surface SP2_s′ of the intermediate supporter pattern SP2′ and the tangent of the external side surface 170_2s′ of the second lower electrode structure 170_2′ may be defined as a second angle θ2. The angle formed by the tangent of the side surface 170_2s′ may be defined as the second angle θ2. The second angle θ2 in the intermediate region MR may be greater than the first angle θ1 in the upper region UR. The second angle θ2 may increase toward the upper surface of the substrate 101 in the intermediate region MR.

In the lower region LR, at the point at which the lower supporter pattern SP3′ and the second lower electrode structure 170_2′ are in contact with each other, the angle formed by the tangent of the external side surface SP3_s′ of the lower supporter pattern SP3′ and the tangent of the external side surface 170_2s′ of the second lower electrode structure 170_2′ may be defined as a third angel θ3. The third angle θ3 in the lower region LR may be greater than the second angle θ2 in the intermediate region MR. The third angle θ2 may increase toward the upper surface of the substrate 101 in the lower region LR.

Referring to FIGS. 6A to 6C, in the upper, intermediate, and lower regions UR, MR, and LR, open patterns OP1′, OP2′, and OP3′ may be defined.

In the upper region UR, the upper open pattern OP1′ may be defined by the upper supporter patterns SP1′ and the plurality of second lower electrode structures 170_2′. Specifically, the upper open pattern OP1′ may be defined by the external side surface SP1_s′ of the upper supporter patterns SP1′ and the external side surface 170_2s′ of the second lower electrode structures 170_2′. The upper open pattern OP1′ may extend in the horizontal direction.

In the intermediate region MR, the intermediate open pattern OP2′ may be defined by the intermediate supporter patterns SP2′ and the plurality of second lower electrode structures 170_2′. Specifically, the intermediate open pattern OP2′ may be defined by the external side surface SP2_s′ of the intermediate supporter patterns SP2′ and the external side surface 170_2s′ of the second lower electrode structures 170_2′. The intermediate open pattern OP2′ may extend in the horizontal direction.

In the lower region LR, the lower open pattern OP3′ may be defined by the lower supporter patterns SP3′ and the plurality of second lower electrode structures 170_2′. Specifically, the lower open pattern OP3′ may be defined by the external side surface SP3_s′ of the lower supporter patterns SP3′ and the external side surface 170_2s′ of the second lower electrode structures 170_2′. The lower open pattern OP3′ may extend in the horizontal direction.

Referring to FIGS. 1 and 2A together, in the upper region UR of the cell region CA, a ration of a horizontal area of the upper open pattern OP1′ to the sum of horizontal areas of the lower electrode structure 170′, the upper supporter patterns SP1′, and the upper open pattern OP1′ may be defined as an open pattern ratio OR′. According to example embodiments, the open pattern ratio OR′ may be 30% or less, for example, 20% to 30%, or 24% to 30%. In some example embodiments, an open pattern ratio OR′ corresponding to the intermediate open pattern OP2′ may be less than the open pattern ratio OR′ corresponding to the upper open pattern OP1′ and an open pattern ratio OR′ corresponding to the lower open pattern OP3′ may be less than the open pattern ratio OR′ corresponding to the intermediate open patter OP2′.

Similarly to the example described with reference to FIGS. 1 to 2C, the open patterns OP1′, OP2′, and OP3′ may be configured as regions in which the upper electrode structure 174 is disposed.

Referring to FIGS. 6A to 6C, in the upper, intermediate, and lower regions UR, MR, and LR, a distance, for example a minimum horizontal distance, between the supporter patterns adjacent to each other in the horizontal direction may be different.

In the upper region UR, the first minimum horizontal distance D1 between the upper supporter patterns SP1′ adjacent to each other in the horizontal direction may be defined as the distance obtained by subtracting twice the size of the first radius R1 from the third distance L3. D1=L3-2·R1.

In the intermediate region MR, the second minimum horizontal distance D2 between the intermediate supporter patterns SP2′ adjacent to each other in the horizontal direction may be defined as a distance obtained by subtracting twice the size of the second radius R2 from the third distance L3. D2=L3-2·R2.

In the lower region LR, the third minimum horizontal distance D3 between the lower supporter patterns SP3′ horizontally adjacent to each other may be defined as a distance obtained by subtracting twice the size of the third radius R3 from the third distance L3. D3=L3-2·R3.

As described above, the third radius R3 may be greater than the second radius R2, such that the third minimum horizontal distance D3 may be smaller than the second minimum horizontal distance D2. Similarly, the second radius R2 may be greater than a first radius R1, such that the second minimum horizontal distance D2 may be smaller than the first minimum horizontal distance D1.

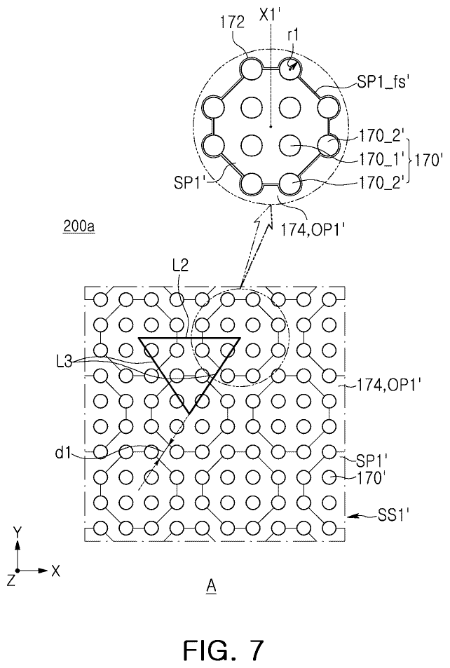

FIG. 7 is an enlarged diagram illustrating a portion of a semiconductor device according to example embodiments.

Referring to FIG. 7, a semiconductor device 200a according to some example embodiments may be the same or similar to the example described with reference to FIG. 1, and FIG. 6A to FIG. 6C other than the configuration in which the external side surface SP1_fs′ of the upper supporter pattern SP1′ has a flat surface.

Referring to FIG. 7, when the external side surfaces SP1_fs′ of the upper supporter pattern SP1′ are extended in a conceptual plurality of linear lines and are connected to each other, the upper supporter pattern SP1′ may be interpreted as having a regular hexagonal shape.

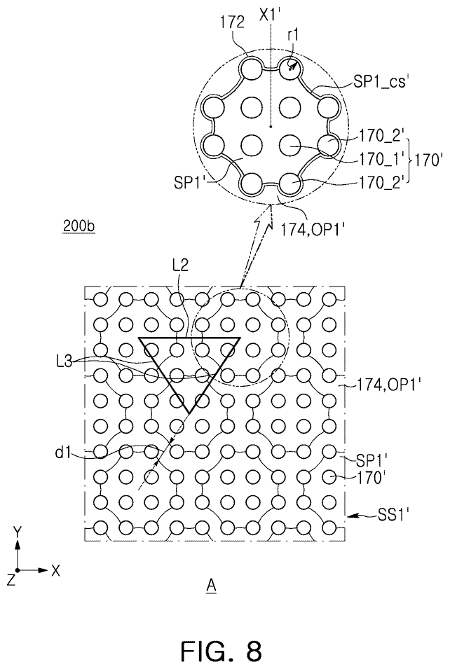

FIG. 8 is an enlarged diagram illustrating a portion of a semiconductor device according to example embodiments.

Referring to FIG. 8, a semiconductor device 200b according to some example embodiments may be the same or similar to the example described with reference to FIGS. 1 and 6A to 6C other than the configuration in which the external side surface SP1_cs′ of the upper supporter pattern SP1′ has a concave surface.

A curvature of the external side surface SP1_cs′ of the upper supporter pattern SP1′ may decrease from the upper region UR to the lower region LR. For example, the curvature in the lower region LR may be smaller than the curvature in the upper region UR. More specifically, in sine example embodiments, a shape of the external side surface SP1_cs′ of the upper supporter pattern SP1′ may become similar to that of the external side surfaces SP1_fs′ of the upper supporter pattern SP1′ described with reference to FIG. 7 from the upper region UR toward the lower region LR.

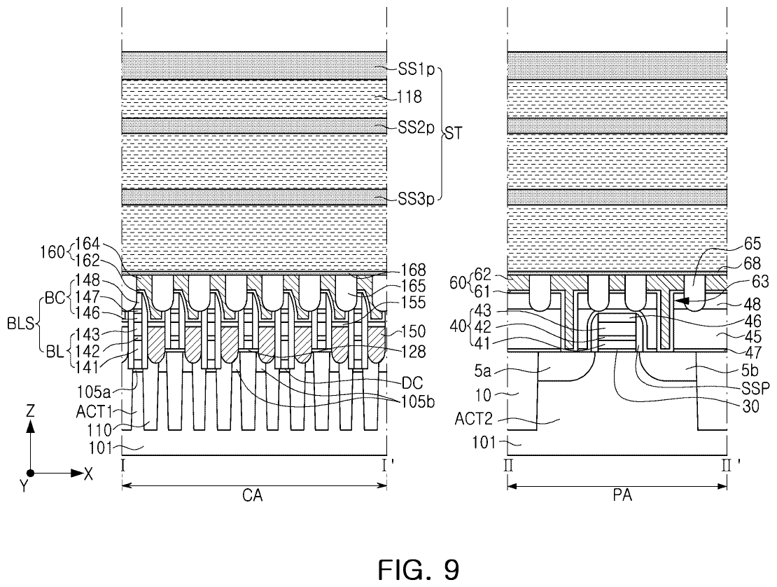

FIGS. 9 to 20 are vertical cross-sectional diagrams illustrating processes of a method of manufacturing a semiconductor device according to some example embodiments.

Referring to FIG. 9, a mold structure ST may be formed on a lower structure including a substrate 101, a wordline, and a bitline structure BLS.

The mold structure ST may be formed by conformally forming an etch stop layer 168 on a lower structure and alternately stacking mold layers 118 and preliminary supporter structures SS1p, SS2p, and SS3p on the etch stop layer 168. The mold structure ST may be disposed in the cell region CA, the interface region IA and the peripheral circuit region PA.

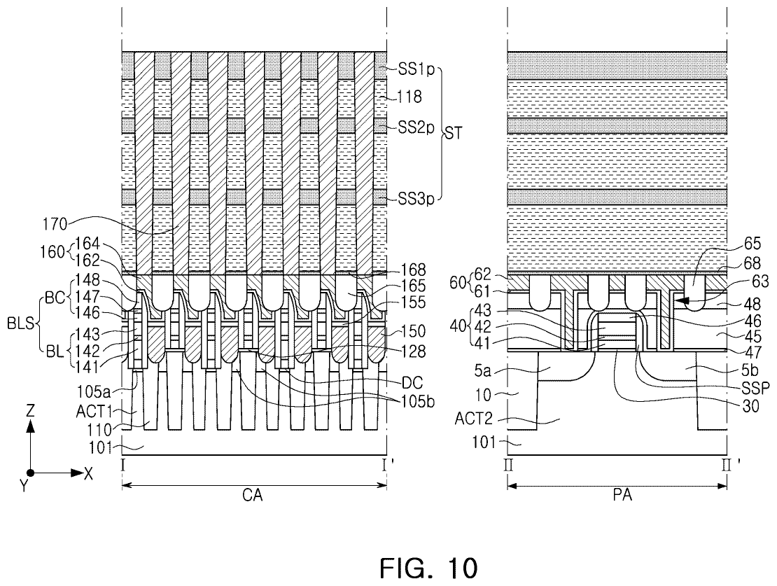

Referring to FIG. 10, in the cell region CA, the lower electrode structures 170 may be formed in the mold structure ST.

The lower electrode structures 170 may be formed by forming a hole by etching the mold structure ST and the etch stop layer 168 to expose the upper conductive pattern 160, and filling the hole with a conductive material. The lower electrode structures 170 may be disposed in a honeycomb structure as illustrated in FIG. 2A.

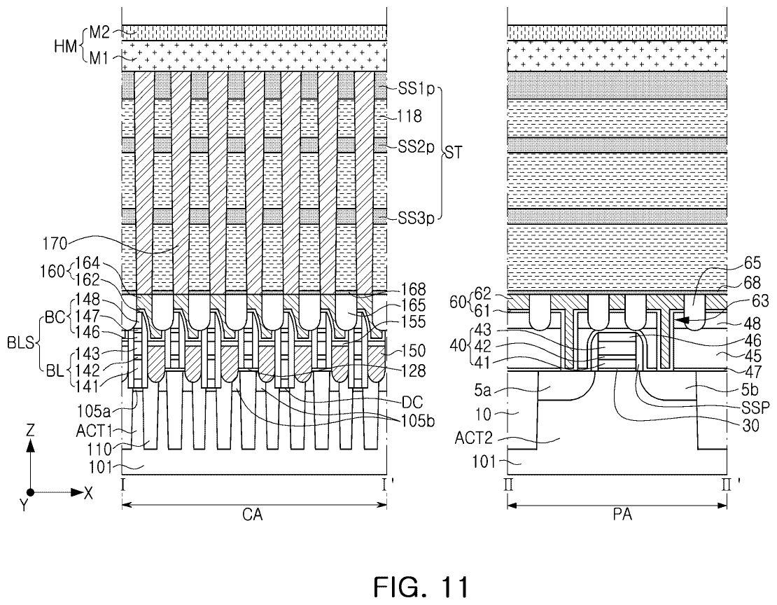

Referring to FIG. 11, a hard mask HM may be formed on the mold structure ST across the cell region CA and the peripheral circuit region PA.

In the hard mask HM, a first layer M1 formed on an upper surface of the mold structure ST and a second layer M2 on the first layer M1 may be formed in order. The first layer M1 may be an amorphous carbon thin film layer deposited by a CVD method, and the second layer M2 may be formed by a spin coating method and may include silicon oxynitride.

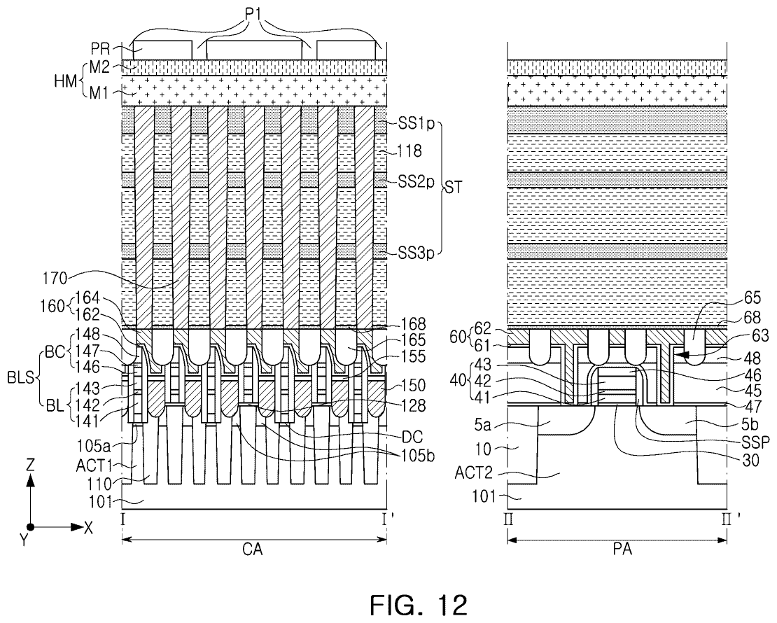

Referring to FIG. 12, a photoresist layer PR having an open region P1 may be formed on the hard mask HM.

When viewed from above, the shape of the open region P1 of the photoresist layer PR may be the same as a circular shape formed by extending the external side surfaces SP1_s of the upper supporter pattern SP1 in a conceptual curve and connecting the surfaces to each other (see FIG. 2A). In a different point of view, the photoresist layer PR may include a plurality of parts having a cylindrical shape.

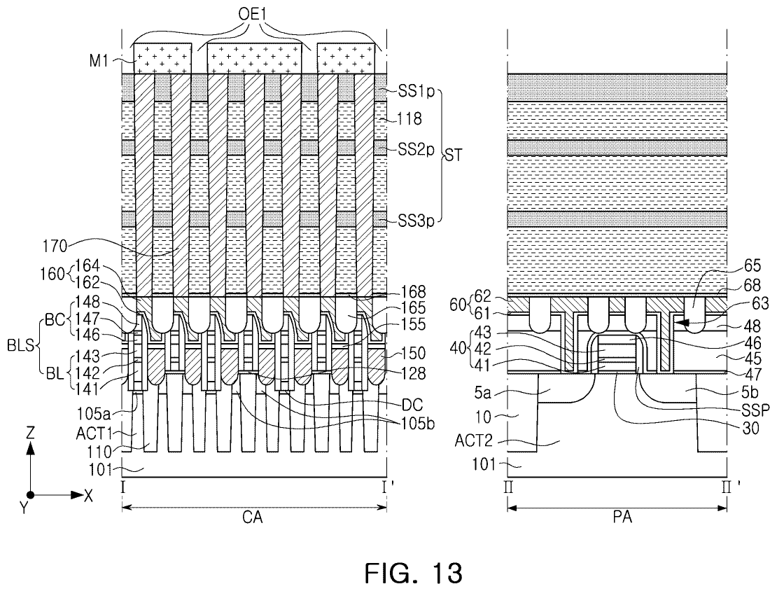

Referring to FIG. 13, the hard mask HM may be patterned using the photoresist layer PR according to FIG. 12.

Referring to FIG. 13, the hard mask HM may be patterned using the photoresist layer PR such that at least a portion of an upper surface of the mold structure ST may be exposed. Accordingly, the patterned hard mask HM may have a first etch region OE1.

By the patterning, the entire upper surface of the mold structure ST may be exposed in the peripheral circuit region PA.

The photoresist layer PR and the patterned second layer M2 may be removed such that only the patterned first layer M1 may remain. Here, the patterned second layer M2 may not be removed and may remain along with the patterned first layer ML.

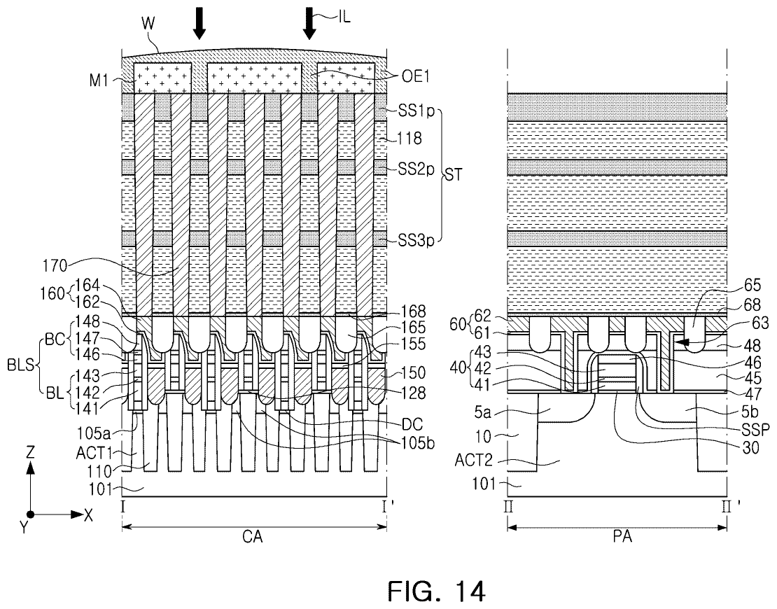

Referring to FIG. 14, an exposure device may be disposed on the first layer M1 (or hard mask HM) having the first etch region OE1, and a predetermined solvent W may be applied between the first layer M1 and a lens of the exposure device.

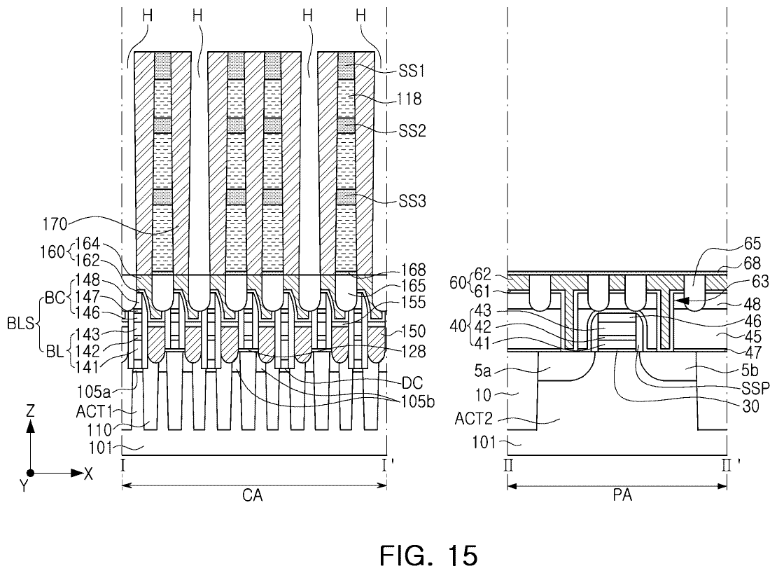

Referring to FIGS. 14 and 15 together, the etch region H penetrating the preliminary supporter structures SS1p, SS2p, and SS3p and mold layers 118 may be formed by the immersion exposure method IL. Here, the immersion exposure method IL may be argon fluoride immersion exposure (ArF immersion lithography), and the predetermined solvent W may include water. According to some example embodiments, by forming the etch region H through the argon fluoride immersion lithography (ArF immersion lithography) method, the limitations of the minimum pitch between supporter patterns may be addressed and a cost reduction effect may be obtained.

Referring to FIG. 15, by the immersion exposure method IL, an etch region H penetrating the preliminary supporter structures SS1p, SS2p, and SS3p and the mold layers 118 may be formed such that a surface of the etch stop layer 168 may be exposed.

In the peripheral circuit region PA, the mold structure ST may be entirely removed. Thereafter, the remaining hard mask HM and the predetermined solvent W may be removed.

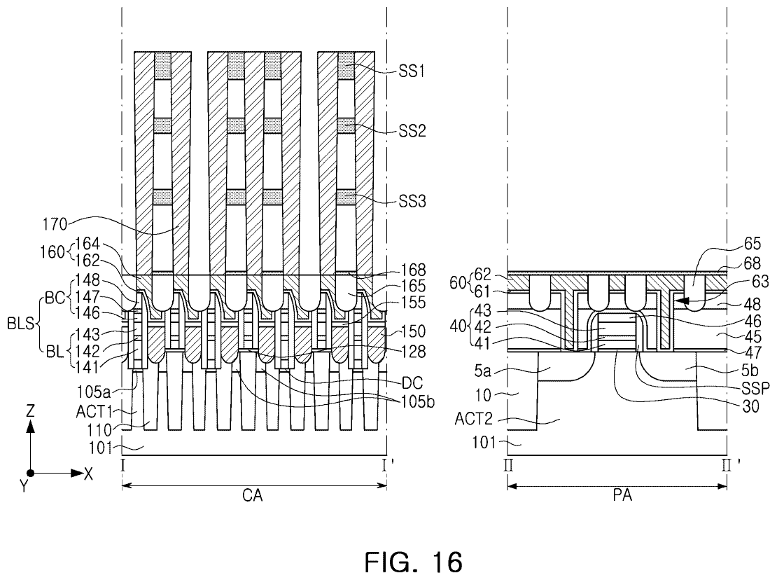

Referring to FIG. 16, the remaining mold layers 118 in the cell region CA and the peripheral circuit region PA may be selectively removed.

Accordingly, side surfaces of the lower electrode structures 170 may be exposed, and the plurality of supporter structures SS1, SS2, and SS3 supporting the lower electrode structures 170 on different levels may be formed.

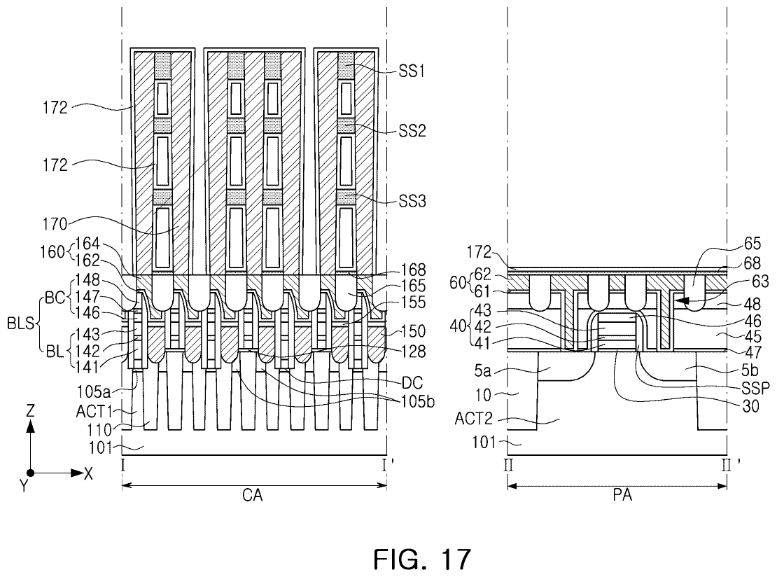

Referring to FIG. 17, the dielectric layer 172 may be formed conformally along surfaces of the lower electrode structures 170 and the supporter structures SS1, SS2, and SS3. The dielectric layer 172 may also cover the etch stop layer 168 and the etch stop layer 68.

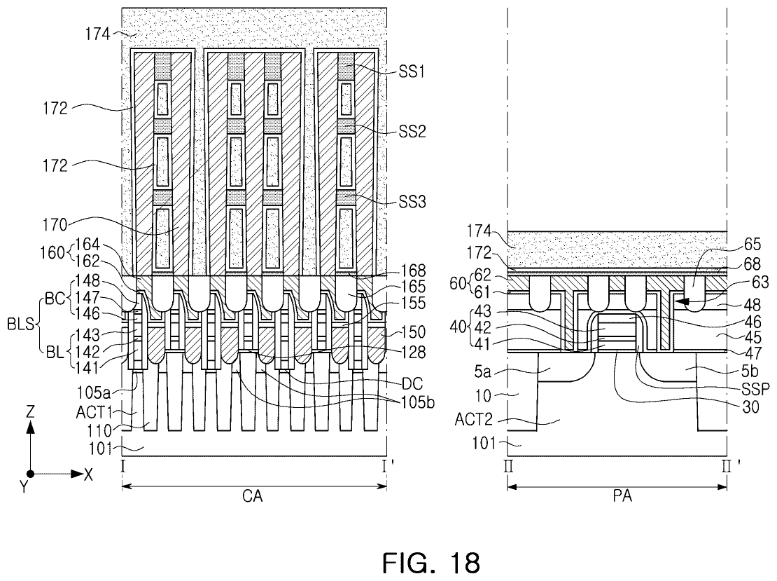

Referring to FIG. 18, an upper electrode structure 174 covering the dielectric layer 172 may be formed in the cell region CA, the interface region IA and the peripheral circuit region PA. The upper electrode structure 174 may fill a space between the lower electrode structures 170 and may cover the lower electrode structures 170 and the supporter structures SS1, SS2, and SS3. The lower electrode structures 170, the dielectric layer 172 and the upper electrode structure 174 may form a data storage structure CAP.

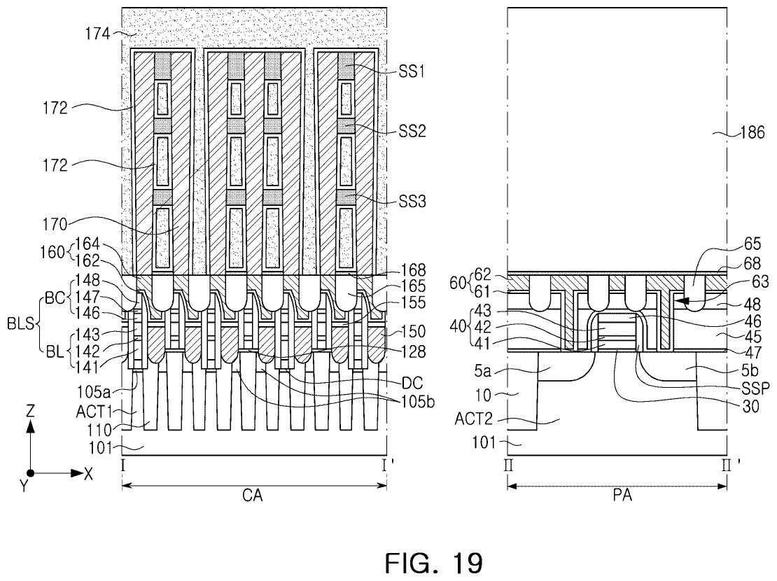

Referring to FIG. 19, the dielectric layer 172 and the upper electrode structure 174 in the peripheral circuit region PA may be removed by an etching process. Accordingly, the etch stop layer 68 may be exposed.

A lower interlayer insulating layer 186 may be formed on the exposed etch stop layer 68. The lower interlayer insulating layer 186 may also be formed on the etch stop layer 168 in an interface region IA (not illustrated). A planarization process may be performed on the lower interlayer insulating layer 186 such that the lower interlayer insulating layer 186 may be present on the same level as a level of an upper surface of the upper electrode structure 174.

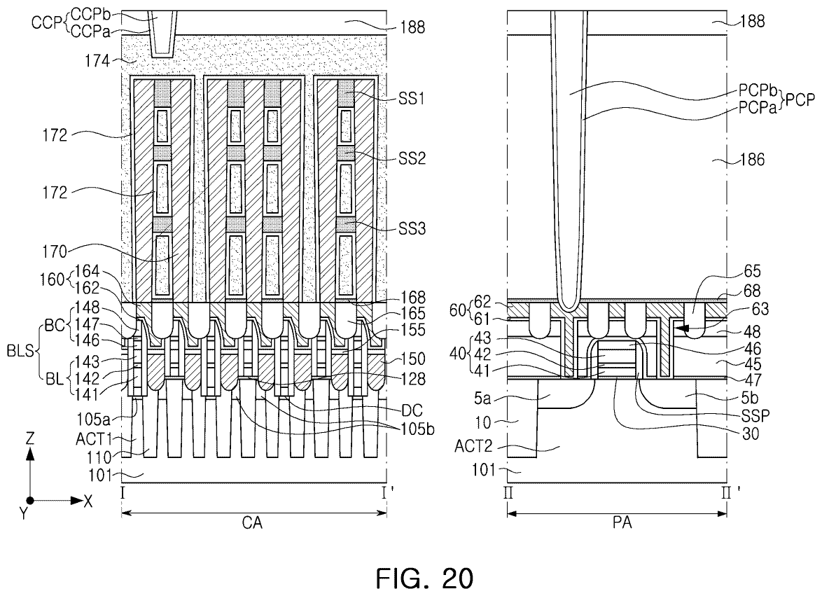

Referring to FIG. 20, an upper interlayer insulating layer 188 may be formed on the upper electrode structure 174 and the lower interlayer insulating layer 186.

Thereafter, in the cell region CA, the cell contact plug CCP may penetrate the upper interlayer insulating layer 188 and may be connected to the data storage structure CAP. In the peripheral circuit region PA, the peripheral contact plug PCP may penetrate the upper interlayer insulating layer 188 and the lower interlayer insulating layer 186 and may be connected to the peripheral interconnection 60.

Thereafter, referring to FIG. 2B, an interlayer insulating layer ILD may be formed on the upper interlayer insulating layer 188, and the upper contact plugs 92 and 95 penetrating the interlayer insulating layer ILD may be formed, such that the semiconductor device 100 may be manufactured.

According to the aforementioned example embodiments, a semiconductor device including a supporter structure having various designs depending on the arrangement of the data storage structure may be provided.

Specifically, a semiconductor device including a supporter pattern having various designs according to the arrangement of the lower electrode structure of the data storage structure in the horizontal may be provided.

More specifically, by providing a semiconductor device including supporter patterns patterned to be in contact with the plurality of second lower electrode structures surrounding the first lower electrode structure and most adjacent to the first lower electrode structure, the limitation of the minimum pitch between the supporter patterns may be addressed in a patterning process.

While some example embodiments have been illustrated and described above, it will be configured as apparent to those skilled in the art that modifications and variations may be made without departing from the scope in the example embodiments as defined by the appended claims.

What is claimed is:

1. A semiconductor device, comprising:
an integrated circuit structure including conductive regions;
a capacitor including lower electrode structures electrically connected to the conductive regions of the integrated circuit structure, a dielectric layer covering the lower electrode structures, and an upper electrode structure on the dielectric layer, the lower electrode structures being spaced apart from each other on the integrated circuit structure; and
supporter structures interconnecting the lower electrode structures,
wherein the supporter structures include,
an upper supporter structure interconnecting upper regions of the lower electrode structures to each other, the upper supporter structure including upper supporter patterns spaced apart from each other, and
a lower supporter structure including lower supporter patterns interconnecting the lower electrode structures to each other, the lower supporter patterns spaced apart from each other below the upper supporter patterns,
wherein external side surfaces of the upper supporter patterns of the upper supporter structure and external side surfaces of the upper regions of the lower electrode structures connected to each other by the upper supporter patterns define an upper open pattern extending in a horizontal direction,
wherein external side surfaces of the lower supporter patterns of the lower supporter structure and external side surfaces of the lower electrode structure connected to each other by the lower supporter patterns define a lower open pattern extending in the horizontal direction, and
wherein first centers of the upper supporter patterns of the upper supporter structure and second centers of the lower supporter patterns of the lower supporter structure corresponding to the first centers, respectively, are aligned.

2. The semiconductor device of claim 1, wherein each of the upper supporter patterns of the upper supporter structure surrounds at least one first lower electrode structure of the lower electrode structures and each of the upper supporter patterns is in contact with at least a portion of a side surface of each of a plurality of second lower electrode structures adjacent to the first lower electrode structure.

3. The semiconductor device of claim 2,
wherein an external side surface of an upper supporter pattern between second lower electrode structures adjacent to each other among the plurality of second lower electrode structures has a convex shape in a direction away from a center of the upper supporter pattern.

4. The semiconductor device of claim 2,
wherein an external side surface of an upper supporter pattern of the upper supporter patterns between second lower electrode structures adjacent to each other among the plurality of second lower electrode structures has a flat surface.

5. The semiconductor device of claim 2,
wherein an external side surface of an upper supporter pattern of the upper supporter patterns between second lower electrode structures adjacent to each other among the plurality of second lower electrode structures has a concave shape in a direction toward a center of the upper supporter pattern.

6. The semiconductor device of claim 1, wherein each of the upper supporter patterns of the upper supporter structure surround an entire side surface of a first lower electrode structure of the first lower electrode structures and is in contact with a portion of a side surface of each of a plurality of second lower electrode structures adjacent to the first lower electrode structure.

7. The semiconductor device of claim 6, wherein a distance between centers of upper supporter patterns adjacent to each other in the horizontal direction is configured to be 76 nm or more and 100 nm or less.

8. The semiconductor device of claim 6, wherein
at least one of the lower supporter patterns of the lower supporter structure surrounds the first lower electrode structure and is in contact with at least a portion of the side surface of each of the plurality of second lower electrode structures adjacent to the first lower electrode structure, and
the at least one of the lower supporter patterns is between the upper supporter structure and the integrated circuit structure.

9. The semiconductor device of claim 8, wherein a maximum horizontal width of the lower supporter patterns of the lower supporter structure is greater than a maximum horizontal width of the upper supporter patterns of the upper supporter structure.

10. The semiconductor device of claim 8, wherein, in a plan view, circumferential surfaces of the second lower electrode structures are in contact with internal side surfaces of the lower supporter patterns.

11. The semiconductor device of claim 1, wherein at least one of the upper supporter patterns of the upper supporter structure surrounds entire side surfaces of a plurality of first lower electrode structures of the lower electrode structures, the plurality of first lower electrode structures being most adjacent to each other, and the at least one of the upper supporter patterns is in contact with at least a portion of a side surface of each of a plurality of second lower electrode structures adjacent to the each of the first lower electrode structures.

12. The semiconductor device of claim 11, wherein a distance between centers of the upper supporter patterns adjacent to each other in the horizontal direction is configured to be 95 nm or more and 110 nm or less.

13. The semiconductor device of claim 1, further comprising:
an intermediate supporter structure between the upper supporter structure and the lower supporter structure,
wherein the intermediate supporter structure includes intermediate supporter patterns interconnecting the lower electrode structures to each other and spaced apart from each other, and
wherein an external side surface of the intermediate supporter patterns of the intermediate supporter structure and external side surfaces of the lower electrode structures connected to each other by the intermediate supporter patterns define an intermediate open pattern extending in the horizontal direction.

14. The semiconductor device of claim 13, wherein third centers of the intermediate supporter patterns of the intermediate supporter structure are aligned with the first centers and the second centers corresponding to the third centers.

15. The semiconductor device of claim 13,
wherein a maximum horizontal width of an intermediate supporter pattern of the intermediate supporter patterns is greater than a maximum horizontal width of an upper supporter pattern of the upper supporter patterns, and
wherein a maximum horizontal width of a lower supporter pattern of the lower supporter patterns is greater than a maximum horizontal width of the intermediate supporter pattern.

16. The semiconductor device of claim 1, wherein the upper open pattern and the lower open pattern are filled by the upper electrode structure.

17. A semiconductor device, comprising:
an integrated circuit structure including conductive regions;
a capacitor including lower electrode structures electrically connected to the conductive regions of the integrated circuit structure, a dielectric layer covering the lower electrode structures, and an upper electrode structure on the dielectric layer;
an upper supporter structure including upper supporter patterns spaced apart from each other, each of the upper supporter patterns surrounds at least one first lower electrode structure of the lower electrode structures and each of the upper supporter patterns is in contact with at least a portion of a side surface of each of a plurality of second lower electrode structures adjacent to the at least on first lower electrode structure; and
a lower supporter structure below the upper supporter structure and including lower supporter patterns having centers aligned with centers of the upper supporter patterns, respectively,
wherein at least a portion of the upper electrode structure of the capacitor surrounds a side surface of each of the upper supporter patterns and extends in a horizontal direction between the upper supporter patterns, and
wherein at least a portion of the upper electrode structure of the capacitor surrounds a side surface of each of the lower supporter patterns and extends in the horizontal direction between the lower supporter patterns.

18. The semiconductor device of claim 17, wherein, in a plan view, a portion of the at least one first lower electrode structure is not surrounded by the dielectric layer.

19. A semiconductor device, comprising:
an integrated circuit structure including conductive regions;
a capacitor including lower electrode structures electrically connected to the conductive regions of the integrated circuit structure, a dielectric layer covering the lower electrode structures, and an upper electrode structure on the dielectric layer; and
a supporter structure including a supporter pattern group being sequentially located at different levels on the integrated circuit structure, the supporter pattern group surrounds at least one first lower electrode structure of the lower electrode structures on different levels and contacts at least a portion of a side surface of each of a plurality of second lower electrode structures adjacent to the at least one first lower electrode structure,
wherein the supporter pattern group of the support structure includes,
upper supporter patterns in an upper region of the lower electrode structures and spaced apart from each other in a horizontal direction;
intermediate supporter patterns below the upper supporter patterns, and having centers aligned with centers of the upper supporter patterns; and
lower supporter patterns between the intermediate supporter patterns and the integrated circuit structure and having centers aligned with centers of the intermediate supporter patterns, respectively,
wherein a minimum distance between external side surfaces of the upper supporter patterns adjacent to each other among the upper supporter patterns is greater than a minimum distance between external side surfaces of the intermediate supporter patterns adjacent to each other among the intermediate supporter patterns, and
wherein a minimum distance between external side surfaces of the intermediate supporter patterns adjacent to each other among the intermediate supporter patterns is greater than a minimum distance between external side surfaces of the lower supporter patterns adjacent to each other among the lower supporter patterns.

20. The semiconductor device of claim 19,
wherein a first angle between a side surface of a lower supporter pattern of the lower supporter patterns and at least one side surface of the plurality of second lower electrode structures is greater than a second angle between a side surface of an intermediate supporter pattern of the intermediate supporter patterns and at least one side surface of the plurality of second lower electrode structures, and
wherein the second angle is greater than a third angle between a side surface of an upper supporter pattern of the upper supporter patterns and at least one side surface of the plurality of second lower electrode structures.
